(19) United States
(12) Patent Application Publication
(10) Pub. No.: US 2012/0154162 A1
(43) Pub. Date: Jun. 21, 2012

(54) USE OF MANUFACTURING INFORMATION DURING THE OPERATION OF A CONCENTRATED PHOTOVOLTAIC SYSTEM

(75) Inventors: Roeland Vandevelde, American Canyon, CA (US); Wayne Miller, Los Altos, CA (US); Brian Hinman, Los Gatos, CA (US)

(73) Assignee: GREENVOLTS, INC., FREMONT, CA (US)

(21) Appl. No.: 13/227,743

(22) Filed: Sep. 8, 2011

Related U.S. Application Data
(60) Provisional application No. 61/424,537, filed on Dec. 17, 2010.
(60) Provisional application No. 61/424,515, filed on Dec. 17, 2010.
(60) Provisional application No. 61/424,518, filed on Dec. 17, 2010.
(60) Provisional application No. 61/424,493, filed on Dec. 17, 2010.

(51) Int. Cl. G08B 21/00; G01W 1/00; H01L 31/042; G06F 15/00

(52) U.S. Cl. 340/635; 702/188; 702/3; 136/244

(57) ABSTRACT

Storing manufacturing data in a relational database associated with a central backend management system. A plurality of concentrated photovoltaic (CPV) arrays are located at a remote solar site. Each of the CPV arrays and the components making up that CPV array is associated with its set of manufacturing data. The manufacturing data of the CPV arrays and the components making up that CPV array includes serial number information of the components of the CPV arrays and measured manufacturing data for those components, which allows a calculation of at least projected performance information of the CPV array during an actual operation of that CPV array at the remote solar site. Comparing the projected performance information of the CPV array to the actual performance information during the actual operation of that CPV array at the solar site.

### RELATED APPLICATIONS

This application claims the benefit under 35 USC 119 of and priority to U.S. Provisional Application titled “INTEGRATED ELECTRONICS SYSTEM” filed on Dec. 17, 2010 having application Ser. No. 61/424,537, U.S. Provisional Application titled “TWO AXIS TRACKER AND TRACKER CALIBRATION” filed on Dec. 17, 2010 having application Ser. No. 61/424,515, U.S. Provisional Application titled “PV CELLS AND PADDLES” filed on Dec. 17, 2010 having application Ser. No. 61/424,518, and U.S. Provisional Application titled “ISIS AND WIFI” filed on Dec. 17, 2010 having application Ser. No. 61/424,493.

### NOTICE OF COPYRIGHT

A portion of the disclosure of this patent document contains material that is subject to copyright protection. The copyright owner has no objection to the facsimile reproduction by anyone of the interconnect as it appears in the Patent and Trademark Office Patent file or records, but otherwise reserves all copyright rights whatsoever.

### FIELD

Embodiments of the present invention generally relate to the field of solar power, and in some embodiments, specifically relate to using manufacturing data to manage components in a solar site.

### BACKGROUND

A solar site may include many devices. Each of these devices may be able to provide useful information. There has not been an efficient technique to manage this useful information.

### SUMMARY

Various methods and apparatus are described for a concentrated photovoltaic (CPV) system. In an embodiment, a system includes a plurality of concentrated photovoltaic (CPV) arrays located at a solar site. Each of the CPV arrays is associated with a different system control point (SCP) which is communicatively connected to a central backend management system over an Internet using a secured channel and Hypertext Transfer Protocol Secure (HTTPS). Each of the CPV arrays is associated with a set of manufacturing data stored in a relational database associated with the central backend management system. The manufacturing data includes at least projected performance information and serial number information of components of the CPV arrays. Each of the CPV arrays is contained on a two-axis tracker mechanism. The central backend management system includes an energy model module configured to receive the projected performance information of the components of the CPV array, the actual performance information of the components of the CPV arrays, and condition information at the remote solar site to generate site-specific energy models and/or CPV array specific energy models.

### BRIEF DESCRIPTION OF THE DRAWINGS

The multiple drawings refer to the embodiments of the invention.

FIG. 1 illustrates a block diagram of an example computing system that may use an embodiment of one or more of the software applications discussed herein.

FIG. 2 illustrates a diagram of an embodiment of a network with a central backend management system communicating with multiple solar sites.

FIGS. 3A, 3B, and 3C illustrate diagrams of an embodiment of a pair of concentrated photovoltaic (CPV) paddle assemblies that may be installed at a solar site.

FIG. 4 illustrates a diagram of an embodiment of the physical and electrical arrangement of modules in a representative tracker assembly.

FIG. 5 illustrates diagrams of an embodiment of a solar site with multiple CPV arrays.

FIG. 6 illustrates a diagram of an embodiment of a wireless communication set up at a solar site.

FIG. 7A is a diagram of an embodiment of a system control point at a solar site.

FIG. 7B is an example system diagram for a central backend management system and its interface with a system control point.

FIG. 8 is a diagram that illustrates an example a user interface associated with the central backend management system.

FIG. 9 is a diagram that illustrates an example main dashboard user interface that displays power/energy information.

FIG. 10 is a diagram that illustrates an example main dashboard user interface that displays the power and DNI information.

FIG. 11 is a diagram that illustrates an example main dashboard user interface that displays the tracker information.

FIG. 12 is a diagram that illustrates an example main dashboard user interface that displays the camera information.

FIG. 13 is a diagram that illustrates an example main dashboard user interface that displays the maintenance information.

FIG. 14 is a diagram that illustrates an example main dashboard user interface that displays the SCP and inverters information.

FIG. 15 is a diagram that illustrates an example main dashboard user interface that displays paddle, module, and receivers information.

FIG. 16 is a diagram that illustrates an example main dashboard user interface that displays the alert information.

FIG. 17 is a diagram that illustrates an example main dashboard user interface that displays the performance information.

FIG. 18 is a diagram that illustrates an example main dashboard user interface that displays the configuration information.

FIG. 19 is a diagram that illustrates example modules of a central backend management system that may be used to generate alarms associated with a solar site.

FIG. 20 is a flow diagram that illustrates an embodiment of a process that may be used to process the manufacturing data.

While the invention is subject to various modifications and alternative forms, specific embodiments thereof have been shown by way of example in the drawings and will herein be described in detail. The invention should be understood to not be limited to the particular forms disclosed, but on the contrary, the intention is to cover all modifications, equivalents, and alternatives falling within the spirit and scope of the invention.

### DETAILED DISCUSSION

In the following description, numerous specific details are set forth, such as examples of specific voltages, named components, connections, types of circuits, etc., in order to provide a thorough understanding of the present invention. It will be apparent, however, to one skilled in the art that the present invention may be practiced without these specific details. In other instances, well known components or methods have not been described in detail but rather in a block diagram in order to avoid unnecessarily obscuring the present invention. Further specific numeric references (e.g., a first array, a second array, etc.) may be made. However, the specific numeric reference should not be interpreted as a literal sequential order but rather interpreted that the first array is different from a second array. Thus, the specific details set forth are merely exemplary. The specific details may vary from and still be contemplated to be within the spirit and scope of the present invention.

In general, various methods and apparatus associated with monitoring a solar site by using a browser in a client computing system and connecting to a central backend management system using the Internet are discussed. In an embodiment, manufacturing data associated with components of a plurality of concentrated photovoltaic (CPV) arrays located at a remote solar site is stored. Each of the CPV arrays is coupled with a different system control point (SCP) communicatively connected to a central backend management system. The manufacturing data includes at least projected performance information of the components of the CPV arrays. Each of the CPV arrays is contained on a two-axis tracker mechanism. Actual performance information of the components of the CPV arrays is received from their corresponding SCP using a secured and persistent connection and based on Hypertext Transfer Protocol Secure (HTTPS). Alarm information may be generated based on the actual performance information of the components of the CPV arrays not being consistent with their corresponding projected performance information.

### Client Computing System

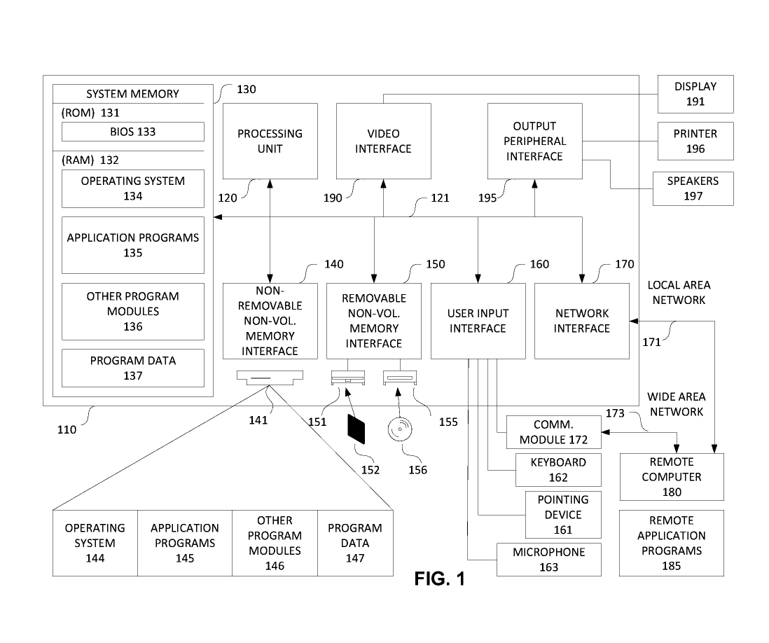

FIG. 1 illustrates a block diagram of an example computing system that may use an embodiment of one or more of the solar power generation site and wireless local area network concepts discussed herein. The wireless LAN allows transmitting commands, parameters, and other information between each of the two axis tracker mechanisms and its various components without having to route cables to those tracker mechanisms.

### Solar Site Network

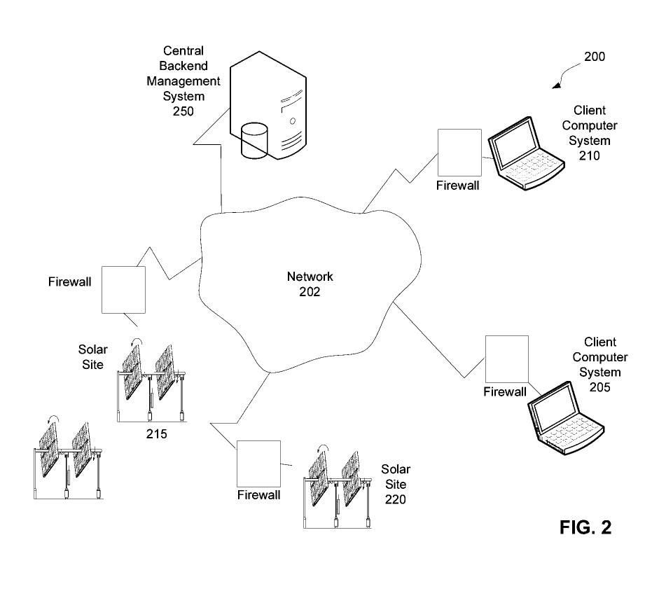

FIG. 2 illustrates a diagram of an embodiment of a network with a central backend management system communicating with multiple solar sites. Diagram 200 may include a network 202, which may be the Internet. A central backend management system 250 may be coupled to the network 200 and configured to enable users to control and manage solar sites from anywhere over the network 200. In the current example, solar sites 215, 220 may be coupled to the network 202. There may be a firewall 216 or 221 at each of the respective solar sites 215, 220.

Each of the solar sites 215, 220 may include many photovoltaic arrays. Each of the photovoltaic arrays is contained in a two-axis tracker mechanism that generates an AC voltage output. Tracker motion control circuitry and electrical power generating circuitry are locally contained on the two-axis tracker mechanism. Each of the photovoltaic arrays is configured with a GPS circuitry to provide position information of the respective photovoltaic array at the solar site. Each of the photovoltaic arrays is configured with wireless communication circuitry to communicate information associated with the respective photovoltaic array to the central backend management system 250.

A user may use a client computing system 205 or 210 to connect to the central backend management system 250 to manage the solar site 215 and/or the solar site 220. Each of the client computing systems 205, 210 may be associated with a browser software to enable the users to use the Internet to access webpages associated with the central backend management system 250. There may be a firewall 206 or 211 associated with each of the client computing systems 205 and 210.

The central backend management system 250 may be configured to provide a large scale management system for monitoring and controlling many solar sites. From anywhere, a user with authorization and privileges can connect to the network 202 and monitor and control the paddles and solar site where the paddles are located. Each solar site may also have a video camera configured to provide information about what is happening at the solar site. The central backend management system 250 may use software as a service type model with secure networking to allow remote controlling and monitoring of the components at the solar site over the Internet. The software as a service can be software that is deployed over the Internet and is deployed to run behind a firewall on a private network. With the software as a service, application and data delivery is part of the utility computing model, where all of the technology is in the “cloud” accessed over the Internet as a service. The central backend management system 250 may be associated with a database, which may be configured to store information received from the various solar sites.

Using the client computing system 210, a user may be able to view information about the solar site including, for example, the signal strength of the wireless router for every CPV array, the temperature of the inverter board, the position of every axis for every CPV array in relation to the sun, whether each axis of a CPV array is tracking, the accuracy of the tracking, the date and time when the tracker of a CPV array was last calibrated, basic predefined graphs on the portfolio, site, section, and array or string dashboard as a graph for a certain time period (e.g., one hour, one day, one week, one month, one year, etc.), the energy production performance as related to all the strings of a CPV array or all the substrings of a string, etc.

### Concentrated Photovoltaic (CPV) Array at a Solar Site

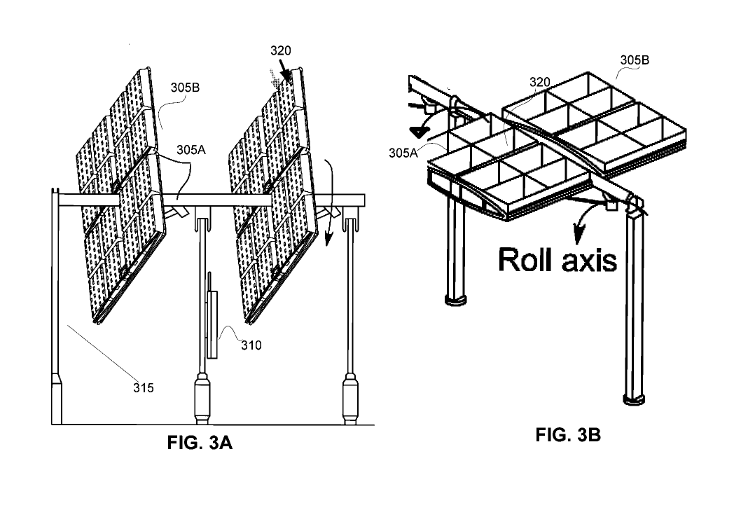

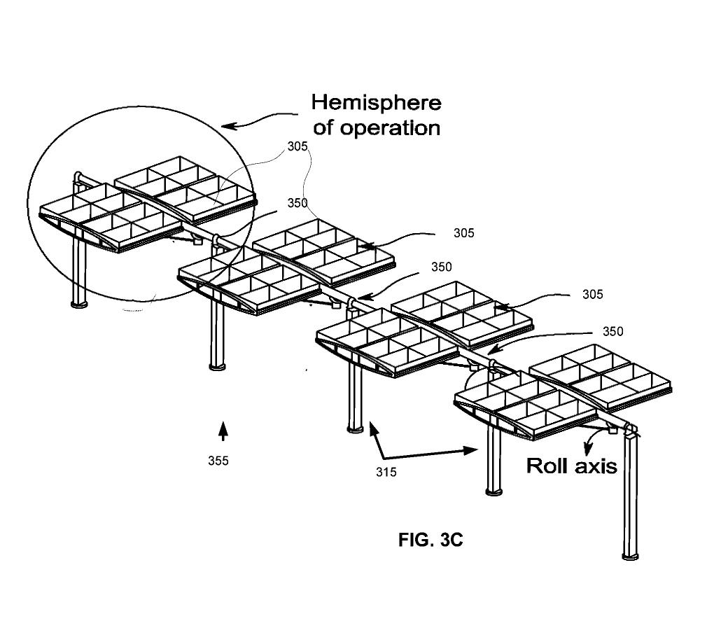

FIGS. 3A, 3B, and 3C illustrate diagrams of an embodiment of a pair of CPV paddle assemblies that may be installed at a solar site. Illustrated in FIG. 3A is a paddle pair 305A and 305B which has its own section of roll beam and own tilt axle. This may allow independent movement and optimization of the paddle pair 305A, 305B with respect to other paddle pairs in a tracker assembly. The movement of the paddle pair 305A, 305B may be limited within an operational envelope. The paddle pair 305A, 305B may be supported by a stanchion 315 and may be associated with an integrated electronics housing of a local system control point (SCP) 310. As illustrated in FIG. 3B, each of the paddles 305A, 305B may include eight (8) modules of CPV cells 320. The module may be the smallest field replaceable unit of the CPV paddle 305A or 305B. The paddles 305A, 305B and their respective modules may be assigned manufacturing data when they were manufactured. When the paddles 305A, 305B and their respective modules are installed in a solar site, their position information and associated manufacturing data may be recorded and stored in a manufacturing data database. The manufacturing data database may be associated with the central backend management system 250.

Illustrated in FIG. 3C is one 16 Kilowatts (KW) CPV solar array that includes eight (8) CPV paddle assemblies 305 mounted on four (4) tilt axle and a common roll beam assembly 350. As illustrated, the tracker assembly 355 is supported by five (5) stanchions, including the three shared stanchions in the middle and a non-shared stanchion at each end. At the shared and non-shared stanchions, the ends of the conical roll beams of each roll beam couple, for support, into the roller bearings. The tracker assembly 355 includes the conical shaped sections of roll beam (fixed axle) with multiple paddle-pair tilt-axle pivots perpendicular to the roll beam.

The CPV paddle assemblies 305 are associated with the SCP 310. In general, there may be one SCP for each CPV paddle assembly (also referred to as a CPV array). For some embodiments, the SCP 310 may include motion control circuits, inverters, ground fault circuits, etc. The SCP 310 may be an integrated electronics housing that is a weather-tight unit. The SCP 310 controls the movement of the tracker assemblies 355, receives DC power from the modules, converts the DC power to AC power, sends the AC power to a power grid, and collects and reports performance, position, diagnostic, and weather data to the central backend management system 250.

### Tracker Assembly for a CPV Array at a Solar Site

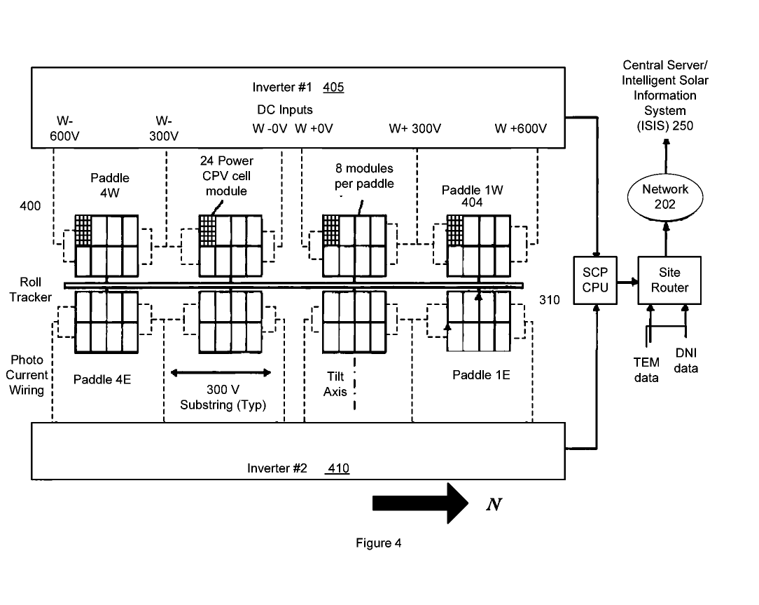

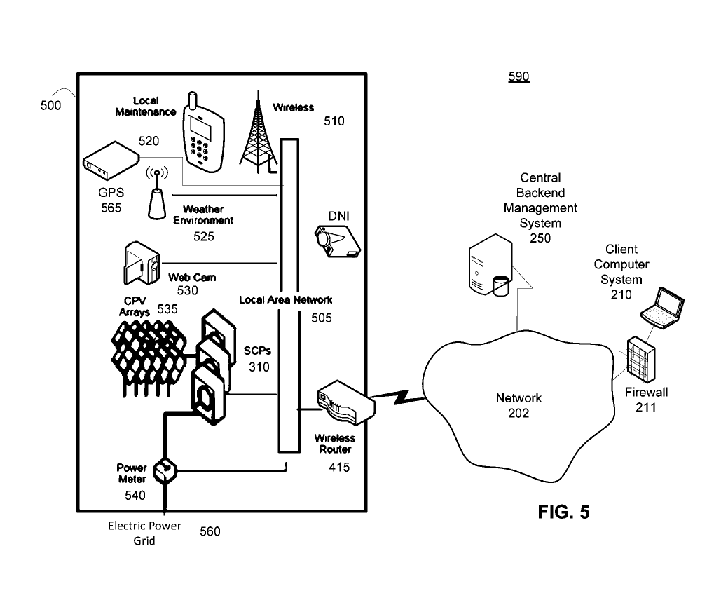

FIG. 4 illustrates a diagram of an embodiment of the physical and electrical arrangement of modules in a representative tracker assembly. In diagram 400, there is one CPV array with eight paddles 430 and two inverters 405 and 410. There are also twenty-four power units per module, eight modules per paddle, two paddles per tilt axis, and four independently-controlled tilt axes per common roll axis. The bi-polar voltage from the set of paddles may be, for example, a +600 VDC and a −600 VDC making a 1200 VDC output coming from the CPV modules. The CPV module array may be a string/row of PV cells arranged in an electrically series arrangement of two 300 VDC panels adding together to make the +600 VDC, along with two 300 VDC panels adding together to make the −600 VDC. Also illustrated in FIG. 4 are the SCP 310, the network or the cloud 202, and a router 415. As will be described with FIG. 5, wireless communication is used to transmit information between the SCP 310 and the router 415. It may be noted that the router 415 also receives direct normal irradiation (DNI) data 420 and temperature/weather data 425. It may also be noted that the central backend management system 250 illustrated in FIG. 2 may also be referred to as an Intelligent Solar Information System (ISIS) or central backend management system 250. The CPV paddles may be arranged in a North South direction, and the CPV modules may be arranged in an East West direction.

### Local Area Network (LAN) at a Solar Site

FIG. 5 illustrates diagrams of an embodiment of a solar site with multiple CPV arrays. Solar site 500 may include a local area network (LAN) 505. Connected to the LAN 505 is radio assembly 510, GPS 565, maintenance hand-held device 520, camera 530, SCPs 310, weather station 525, and power meter 540.

The SCPs 310 are located on the CPV arrays 535. As illustrated in FIG. 3C, there may be one SCP 310 for each of the CPV arrays 535. Each CPV array 535 may include eight (8) paddles, and there may be eight (8) modules per paddle. The SCP 310 may include motion control logic, inverter logic, etc. For example, the motion control logic may allow transitioning the paddles from an operational mode to a stow mode to prevent damage in adverse weather condition (e.g., gust wind, storm, etc.), and the inverter logic may allow converting DC power to AC power. A module in a single SCP may be configured to continuously monitor a local weather station relative to that solar site and broadcast the weather across the LAN to the rest of the SCPs.

For some embodiments, a secured communication channel using Hypertext Transfer Protocol Secure (HTTPS) may be used for transmitting information between the SCP 310 and the central backend management system 250 over the network 202. The SCP 310 may use HTTPS POST to send performance data to the ISIS 250. The SCP 310 may ping the central backend management system 250 periodically (e.g., every one minute) even when the SCP 310 has no data to report. For some embodiments, the central backend management system 250 may respond with acknowledgement in response to the HTTP POST and can optionally send commands to the SCP 310, requests the SCP 310 to maintain a more frequent or permanent connection, throttle the speed of the SCP messages, etc.

For some embodiments, the SCP 310 only has outbound connections and no inbound open connection ports. The SCP 310 may control all the traffic that is sent to the central backend management system 250. It should be noted that the central backend management system 250 does not make inbound calls to the SCP 310. The SCP 310 communicates with all of the other devices (e.g., camera 530, GPS 365, etc.) connected to the LAN 505 and polls data from these devices. The SCP 310 may be associated with a network name and a MAC address, and the SCP 310 may be registered with an on-site DNS server. At predetermined time intervals, the SCP 310 may send power performance data, motion control data, image data, weather data, and direct normal irradiation (DNI) data from the Normal Incidence Pyrheliometer (NIP), etc. to the central backend management system 250. The SCP 310 may include wireless circuitry to transmit information to the central backend management system 250 using wireless communication via the wireless router 415.

The LAN allows faster communications between the devices located at the solar site than when those devices communicate over the Internet with the central backend management system 250. The LAN also includes one device at the site that can provide its information or functionality across the LAN to all of the two-axis tracker mechanisms located at that solar site.

Thus, as discussed above, measured parameters common across the solar site, including DNI and local weather, are detected by a local detector, retrieved by a local device or a combination of both, and then broadcast as internal solar site communications over the LAN to all of the different SCPs at the site. The communications are faster and more reliable because Internet access to such information may occasionally become unavailable from time to time. The measured parameters common across the solar site need only a single detector device rather than one device per two-axis tracker mechanism.

A large number of software packages are resident and hosted in the SCP 310. Some of these may include SCP bi-directionally messaging posts in Extensible Markup Language (XML) to the HTTP(s) server, SCP initiating requests to be commissioned, SCP creating a TLS socket connection to Socket Dock and streams XML, SCP accepting the TLS socket connection to receive XML commands, and many others. The software packages may also be a combination of hardware logic working with programmed or software-coded instructions.

The local video camera 530 may be used to survey the plurality of CPV arrays and to capture video streams/images at the solar site 500. The images captured by the video camera 530 may be polled by the SCP 310 at predetermined time intervals. It may be noted that the video camera 530 can be configured to not send the images to the SCP 310 until the SCP 310 requests for them. The images may then be sent by the SCP 310 to the central backend management system 250. The image format of the video camera 530 may need to be converted into an XML supported format (e.g., base64) and sent to the central backend management system 250 with the data-protocol framework. The images may be time-stamped with the same clock as all of the other SCP data. This allows the central backend management system 250 to correlate the images and the performance data of the various CPV arrays 535. For some embodiments, when the network 202 is not available, the SCP 310 may buffer the video stream/image data in its buffer and send them to the central backend management system 250 when the network 202 becomes available. The SCP 310 may send the video streams/images to the central backend management system 250 at certain time interval (e.g., every five seconds). The video stream/images may be stored by the central backend management system 250 in the associated database. For example, the stored video stream/images may be used to correlate with power/energy performance data during problem determination. There may be one or more video camera 530 at the solar site 500. When there are multiple video cameras 530, the streaming video/images captured by each video camera may be polled by a different SCP.

Each of the CPV arrays 535 may be associated with a GPS 565. The GPS 565 is configured to provide positioning information for the associated CPV array 535 including the longitude and latitude or coordinate information. For example, in commissioning a CPV array 535, the SCP 310 may extract the positioning information from the GPS 565 and transmit it to the central backend management system 250. For some embodiments, the logic for the GPS 565 may be built into the SCP 310.

The weather station 525 may be used to collect local weather information at the solar site 500. That weather information may be collected by the SCP 310 and then transmitted to the central backend management system 250. A solar power meter may be on site to connect to a SCP. The solar power meter may be connected to the LAN 505 using wireless communication. The solar power meter may measure an amount of DNI and broadcast updates of the measured amount of DNI and the time of that measurement. The updates may be transmitted to the central backend management system 250. Local operators may use the maintenance hand-held device 520 to communicate with the other devices in the LAN 505. The power meter 540 is coupled to a power station 560 and is configured to measure power generated by the CPV arrays 535 and distributed to the power grid 560. The power grid 560 may be associated with a client who purchases the power generated by the solar site 500. In this example, the client is Pacific Gas and Electric Company (PG&E). The solar site 500 may include one site wireless router 415 and one or more radio assemblies 510 to enable the SCP 310 to communicate with the central backend management system 250. The combination of the solar site 500 (and other solar sites), the central backend management system 250, the client computing system 210 with its browser (and other client computing systems) may be referred to as a solar power generation and management system.

### Wireless Communication Set Up at a Solar Site

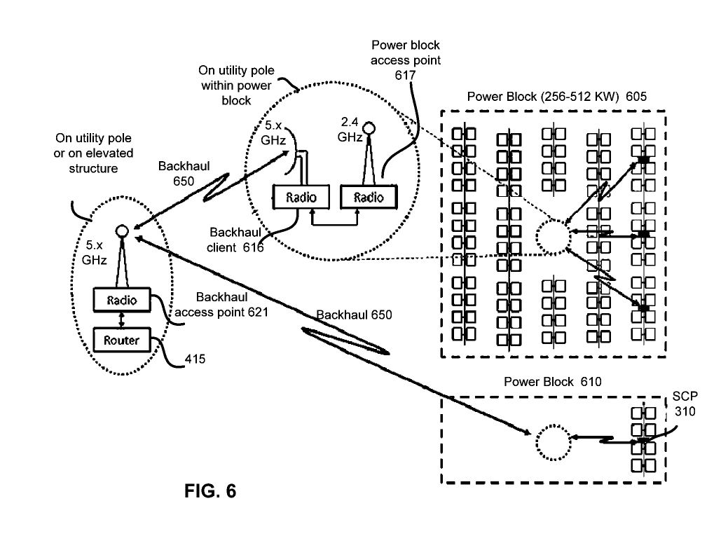

FIG. 6 illustrates a diagram of an embodiment of a wireless communication set up at a solar site. The solar site 500 may include multiple power blocks 605, 610. The power block 605 may be associated with a LAN 505 and may include multiple CPV arrays 535. The power block 605 may also be associated with the radio assembly 510, illustrated in FIG. 5. The radio assembly 510 (also referred to as a power block radio assembly 510) may be installed on a utility pole within the power block 605. For some embodiments, the radio assembly 510 may include a power block access point 617 and a back haul client 616 and an enclosure that contains connect for radio. The enclosure may include wiring connector, AC outlets, etc., and it may be mounted at the bottom of the utility pole. The power block access point 617 may be a 2.4 GHz wireless access point, and the back haul client 616 may be a 5 GHz wireless access point. The antennas associated with the power block access point 617 and the back haul client 616 may be mounted onto a yardarm that is mounted at the top of the utility pole with network cables running from the enclosure from the bottom to the top of the utility pole.

The solar site 500 may also include a backhaul radio assembly 620, which may be installed on a utility pole or an elevated structure. The backhaul radio assembly 620 may include a backhaul access point 621 and the router 415. The backhaul access point 621 is coupled with the backhaul client 616 from each of the power blocks 605, 610 in the solar site 500 over a backhaul network 650. For example, the information collected by the SCP 310 from one or more of the devices connected to the LAN 505 may be transmitted from the SCP 310 using its internal wireless circuitry to the power block radio assembly 510, over the backhaul network 650, to the backhaul radio assembly 620 and its router 415, to the network 202, and eventually to the central backend management system 250.

### System Control Point (SCP)

As described in FIG. 5, the solar power generation and management system includes the central backend management system 250 and many SCPs at the various solar sites. A user using the client computing system 210 may connect to the central backend management system 250 to access information from the components at the solar site 500. The solar site 500 may be protected by a firewall positioned between the SCPs and the Internet.

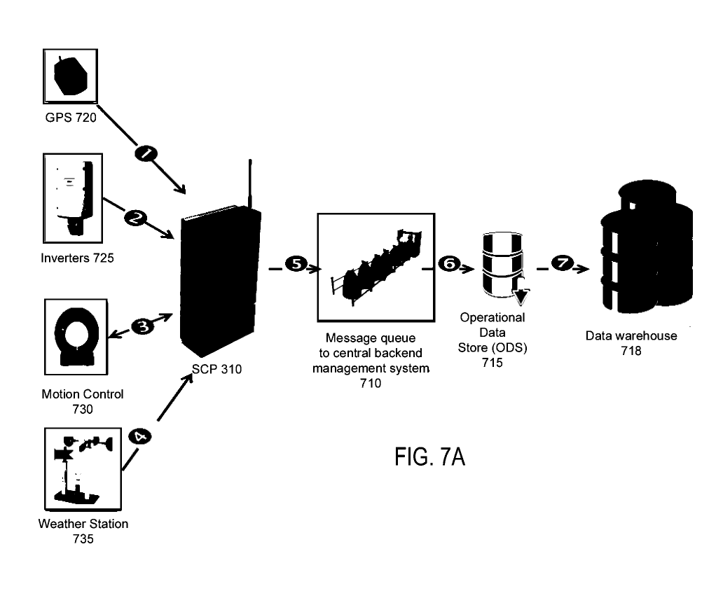

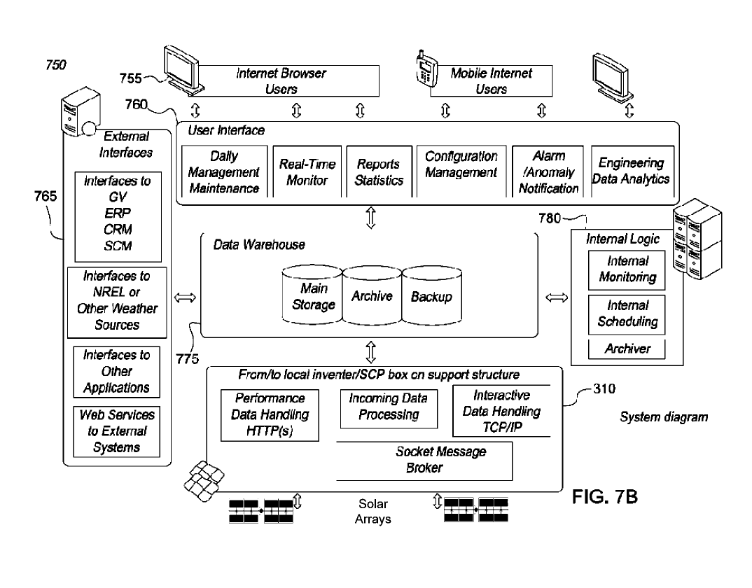

FIG. 7A illustrates a diagram of an embodiment of a system control point at a solar site. Diagram 700 includes the SCP 310 which includes monitoring circuitry and applications to communicate with the various components in the CPV arrays. The SCP 310 is configured to communicate with the central backend management system 250. Communication with the central backend management system 250 may include using the message queue 710. Information transmitted by the SCP 310 to the central backend management system 250 may be stored in the operation data store (ODS) 715 and the data warehouse 718.

When a new SCP and associated CPV array are installed in the solar site, the installation team may record the serial number of the SCP as well as the manufacturing data of all of the components of the associated CPV array. This may include, for example, the serial numbers of the inverters, the motors, the modules, etc. This may also include the manufacturing date and “as built” output voltage level of the modules since each of the modules may have a different output. Reference coordinate information (e.g., the latitude and longitude information) of the CPV array may also be determined. The information recorded by the installation team may be uploaded and stored in the data warehouse 718 associated with the central backend management system 250.

The central backend management system 250 may identify the new CPV array by comparing its actual geographical coordinates to the reference coordinates. The central backend management system 250 may also map the SCP serial number received from the SCP 310 and the SCP serial number recorded by the field installation team to identify the paddles that are installed in the CPV array. The central backend management system 250 may perform various mapping operations including, for example, using the latitude and longitude or GPS information to identify the position of each CPV array in the set of CPV arrays at the solar site. The position of each CPV array may be relative to the positions of other CPV arrays located at the solar site. The central backend management system 250 may store the position information of the CPV array in the database. Each two-axis tracker mechanism at the solar site may be associated with a serial number and GPS coordinates. The central backend management system 250 may use any combination of the serial number and the GPS coordinates for a given tracker as identifier for the two-axis tracker mechanism. This helps the central backend management system 250 to identify which of the two-axis tracker mechanisms that it is communicating.

The central backend management system 250 may send configuration information to the SCP 310 and monitor the SCP 310 and its associated CPV array. The central backend management system 250 may send auto-configuration files over the Internet to a two-axis tracking mechanisms installed at the solar site based on the GPS coordinates of that two-axis tracker mechanisms and its relative position with other two-axis tracker mechanisms located at the solar site according to a layout.

After the SCP 310 is configured, the central backend management system 250 may enable a user to observe what is happening to each of the components of the CPV array in the solar site. For example, the user may be able to compare actual performance data of the CPV array with the projected performance included in the manufacturing data to determine faulty parts. The user may be able to view the power data for the CPV array and the actual weather conditions at the solar site. The user may also be able to view the actual performance data and compare that with the projected data as determined by the manufacturer. The user may be able to compare parameters from the paddles of one CPV array to the parameters of the paddles of neighboring CPV arrays.

From behind a firewall, the SCP 310 communicates with the central backend management system 250 over the Internet (as illustrated in FIG. 2). The SCP 310 may keep this communication (i.e., the socket connection) open until the protocol specific end tag is received. This creates a persistently open outbound connection coming from the SCP 310 out to the central backend management system 250 to work around the firewall at the SCP 310. From a high level, the SCP command architecture is a HTTPS client/server that exchanges XML messages constrained by a specific schema. The central backend management system 250 sends XML commands through a TLS encrypted channel and expects XML responses from the SCP 310. Both the central backend management system 250 and the SCP 310 follow the HTTPS protocol requiring the appropriate headers. HTTPS includes encryption and authentication. HTTPS requires both validation of the source and the receiver of the Internet communications, which can identify the individual SCPs at each solar site by their unique ID embedded in their HTTP communication. The information communicated between the SCPs and the central backend management system 250 may be encrypted.

Each of the SCPs in the solar site is associated with a unique MAC address. The MAC address is assigned by the manufacturer and is part of the manufacturing data. Each of the SCPs in the solar site is also associated with unique GPS coordinates. The GPS coordinates indicates where the SCP is physically located at the solar site. Each of the SCP transmits information to the central backend management system 250 via a centralized wireless router (as described in FIG. 6), and the aggregate communication from all of the SCPs are routed over the Internet to the central backend management system 250.

For some embodiments, each SCP may include a conduit manager configured to provide a direct communication tunnel to the central backend management system 250 by authenticating itself to the central backend management system 250 and establishing an outgoing TCP/IP stream or similar protocol connection to the central backend management system 250. The SCP then keeps that connection open for future bi-directional communication on the established TCP/IP stream connection. A first SCP and a second SCP may cooperate with the central backend management system 250 to provide secure remote access to the set of components in a solar site through their respective firewalls. The central backend management system 250 may be configured to send routed packets for each established TCP/IP stream connection to the intended SCP.

For some embodiments, the SCP 310 may initiate a connection to the central backend management system 250. The central backend management system 250 is configured to map the connection to a corresponding managed device IP address and port. The SCP 310 may send its identification information to the central backend management system 250 for authentication. The central backend management system 250 may maintain a routing table that stores at least real IP addresses, virtual IP addresses, and routes to the many SCPs at the solar site. The direct communication tunnel is a two-way stream connection that may be held opened to the central backend management system 250. Certificate-based Secure Shell (SSH) encryption protocol may be used to ensure secure, end-to-end communication.

The SCP 310 may include routine to generate outbound messages using HTTPS. It establishes a secured persistent outbound connection to the central backend management system 250 and may actively push information to the central backend management system 250. The central backend management system 250 may only need to poll its port/sockets to determine if new data or information is pushed by the SCPs. This is different from the central backend management system 250 having to create a connection to each SCP at the various solar sites and checking to determine if new data or information is present and needs to be pulled from the SCPs.

The SCP 310 may collect the information from the various components of the CPV arrays. For some embodiments, on-board, real time, high resolution performance monitoring test points are built into at least some of the components in the solar site. This may allow the user to control some of these components remotely over the Internet from a client computing system equipped with a browser. This may also allow the user to view monitoring information including alert notification for these components. Thus, the electronic circuits, for example, in the motors, photovoltaic cells, tilt axis, etc., have test points built-in to monitor parameters, and then relay these parameters, via the wireless network (described in FIG. 6) and other network communications, back to the central backend management system 250.

For some embodiments, the SCP 310 for each of the CPV array may contain or be associated with the GPS circuits 720, the electronic circuitry for the inverters 725, tracking or motion control circuitry 730, and the weather station 735. Although not shown, the SCP 310 may also contain power supplies, Wi-Fi circuits, etc. The SCP 310 may collect information associated with these components and transmit the information over the Internet for storage in the ODS 715 and the data warehouse 718.

For some embodiments, there may be one or more master SCPs controlling all of the other SCPs at the solar site. The operations of the components at the solar site may be independent of and therefore may be autonomous from the central backend management system 250. This enables the solar site to continue to operate if a connection with the central backend management system 250 is lost. For some embodiments, the information transmitted by the SCP 310 is time stamped. A data buffer in the SCP 310 may be used to store the information until an acknowledgement for receipt of the information is received from the central backend management system 250. The central backend management system 250 may be associated with a message queue 710 to handle a large amount of information transmitted from two or more SCPs at a given solar site. The message queue 710 may be useful to maintain the flow of information when the connection between the solar site and the central backend management system 250 is disrupted (e.g., the Internet is down). When that situation occurs, the information sent from the SCP 310 is stored in the message queue 710 until the connection is re-established. Since the information is time-stamped, the loss of information due to the drop in the connection is reduced.

For some embodiments, real time alarms and events may be generated by the components of the CPV array and transmitted by the SCP 310 to the central backend management system 250. The central backend management system 250 may be configured to maintain information related to the events, alarms and alerts with a historical set of data for each. An event is generated when something occurs but no action may be necessary. Each event is time stamped. An alert is generated when something occurs that the user needs to be aware of but no action may be necessary. Each alert is time stamped. An alarm is generated when something occurs that require an action to be taken. Each alarm is time stamped. The information transmitted by the SPC 310 may include, for example, total global horizontal irradiance or direct normal insolation (DNI), total global radiation, air temperature, wind speed, cloud conditions, precipitation, ambient temperature at the SCP, AC power, DC power, AC/DC current, AC/DC Voltages, I/V curves coming from an operational model to detect potential problems with the photovoltaic cell array, paddle angles, video camera images of the solar site, GPS coordinates, etc.

As discussed, the current information generated by and/or collected from the individual components of the solar site along with all of the historical information from those components may be maintained in the ODS 715 and the data warehouse 718. Similar information from the other solar sites may also be maintained in the ODS 715 and the data warehouse 718. This allows for better trend analysis. For example, the I-V curves for each panel can be analyzed over time to determine changes. The manufacturing data for the cells in the paddles may also be stored in the manufacturing data database. That database may be part of the ODS 715 and the data warehouse 718. A comparison of the actual performance data to the projected performance data (included in the manufacturing data) for that cell may be determined. Alerts may be generated based on the comparisons of the actual performance data with the projected performance data. Weather conditions, power generation information from a cell or a paddle, and other information from the solar site may be stored in the ODS 715 and the data warehouse 718. The information associated with the various components may be viewed via the user interfaces to enable the user to compare current as well as historical performance information.

The information associated with each of the components may also be monitored and maintained in the manufacturing data database at different levels of granularity. For example, the maintained information may be for an entire portfolio of solar sites, a single solar site, a section of a solar site, a CPV array making up that section, a string of CPV cells feeding an inverter, etc. The information maintained in the database may be viewed along with the live video stream of the solar site. This enables remote monitoring and controlling of the multiple solar sites at the same time using the Internet by logging into the central backend management system 250. In addition, alerts and event notifications may be conveyed from the components and their associated SCPs at each solar site to the central backend management system 250. Various routines may be scripted in programming code to monitor the components for triggering events and alerts to detect faulty components in the solar site. This may include failure conditions related to the tracker position, motor function, string performance, inverter performance, etc. Some of the alerts may be generated based on comparisons of the actual field performance information to threshold values or to projected performance information included in the manufacturing data. The information and the alerts associated with the components and the SCPs may enable a user to obtain a complete picture of what is happening with each solar array at the site at different levels of granularity. The user may also obtain historical data. Comparisons may be performed to help with trend analysis. It may be noted that the SCP 310 can be configured to change the delivery interval for all information from the array at the site level and at the section level.

For some embodiments, each of the SCPs (one per solar array) from solar sites is programmed to transmit periodic heartbeat outbound command to the central backend management system 250 using HTTPS to keep the connection open. For example, the heartbeat may be transmitted every minute. The central backend management system 250 may then tell the SCP what to do by including short commands in the response/acknowledgement message. Note that using the short commands is more efficient that using a whole webpage.

The SCP may transmit HTTPS GET command filled with parameters (e.g., motion control data, weather data, solar data (DNI), inverter data, image/streaming video data, GPS data, power production parameter such as I-V curves, etc.) to the central backend management system 250. In response to receiving the HTTPS GET command, the central backend management system 250 may provide an acknowledgement of the receipt of the GET command with any information or parameters that the central backend management system 250 wants to send to the SCP. The central backend management system 250 may alternatively send an acknowledgement along an action item for the SCP 310 to act on. For example, when the central backend management system 250 recognizes issues such as potential severe weather condition, the central backend management system 250 may send appropriate control information to the SPC to tell the SPC to put the array in the stow mode.

Upon receiving the acknowledgement from the central backend management system 250, the SCP 310 may delete the parameters from its buffer. As mentioned, the parameters may include information generated by the components of the CPV array. This approach allows secure access and management of components in the solar array while they are protected by a firewall. The firewall prevents malicious inbound traffic or unauthorized access by devices external to the solar generation and management system and maintains the integrity of the solar generation and management system. It should be noted that the user is not allowed to use the client computing system to make a connection to the SCP 310. Real time data is collected by the central backend management system 250, and the user may view of the information collected by the SCP by logging into the central backend management system 250.

For some embodiments, the SCP 310 may be periodically poll the socket to check for any new communications. The central backend management system 250 may send XML commands through a secure tunnel encryption protocol, such as a Transport Layer Security (TLS) encrypted channel and expects XML responses. Both the SCP 310 and the central backend management system 250 follow the same HTTPS protocol with the appropriate headers. In an alternative embodiment, a virtual private network (VPN) is maintained between each of the solar sites and the central backend management system 250.

FIG. 7B is an example system diagram for a central backend management system and its interface with a system control point. The system diagram 750 includes client computing systems 755 (e.g., wired and wireless devices) communicating with the central backend management system 250, which includes the internal logic 780 (e.g., internal monitoring, internal scheduling, archiver), the data warehouse 775 (e.g., main storage, archive, backup), and external interfaces 765.

The external interfaces 765 may be used to access external resources (e.g., web services, weather information, customer relationship management (CRM) applications, external applications, etc.) that may be necessary for the central backend management system 250 to operate. For example, the central backend management system may include a web server with a set of feature extension modules such as internet information services. The SCP 310 may simulate browser like communication by using HTTPS commands and responses without the generation of the web page. As mentioned, the central backend management system also receives information from the solar site via the SCP 310 over a secured connection.

Various user interface dashboards 760 are served to the client computing system 755 from the central backend management system 250. The user may also be able to access an array dashboard with daily, weekly, etc. view, an array dashboard on current to voltage (IV) curves (all strings or single string), an array tracking components dashboard, a string of CPV cells supplying DC voltage to an inverter dashboard, a visual browser including on-site camera dashboard, and many others. The dashboard for a portfolio, site, section, array, etc. may provide information about that component so that the user can select to control or monitor it for manufacturing information, configuration information, or performance information.

The central backend management system 250 may be configured to operate as a hosting facility, which collects information from a number of parameters from all of the solar arrays at all of the solar sites. A user may only be able to access the information from the one or more solar sites that the user is authorized. Communication between the central backend management system 250 and the SCP 310 may be performed using HTTPS.

### Remote Management of the Solar Site

As described in FIGS. 2 and 7B, a user may use browser software (e.g., Firefox, Internet Explorer, etc.) installed on the client computing system 205 to connect to the central backend management system 250 via the network or Internet 202. The user may access webpages associated with the central backend management system 250 to view information available from the solar site 215. The user may also use the same connection to manage the solar site 215. For some embodiments, the user may need to register with the central backend management system 250 and be authorized to access information related to the solar site.

The central backend management system 250 may be hosted on one or more servers. Users with mobile or non-mobile client computing systems can also connect to the central backend management system 250 via the Internet. The browser-based access through the central backend management system 250 may be configured to allow near real-time system status and operational control of the arrays at the solar site. The central backend management system 250 is configured to have user authentication features, user search and browse features, command schema for control of components, monitoring of components, and alert notification on components.

The central back-end management system 250 is configured for monitoring and controlling the solar sites in a scalable manner. The central backend management system 250 controls and manages the concentrated photovoltaic (CPV) system from anywhere over a network, such as the Internet. The monitoring and intelligence capability programmed into the central backend management system 250 is not for the most part, located in the end-points of the user's client computing system or local integrated electronic housings for the local system control points; rather the monitoring and intelligence capability is programmed into the central backend management system 250.

The central backend management system 250 collects data from a number of parameters from all of the solar arrays at all of the solar sites. The user obtains network access to one or more sites owned by the user by accessing the central backend management system 250 as a hosting facility. For some embodiments, a virtual private network may be maintained between each solar site and the central backend management system 250. SSL type security for the network along with an authorized user list may be utilized to secure the network between the client computing system over the Internet and to the hosting facility. For some other embodiments, communication between the solar site and the central backend management system 250 may be based on HTTPS. Other similar security protocols may be employed between the central backend management system (the hosting facility) and each solar site. Thus, when the user wants to interact with or even monitor the solar site, the user can use the browser of the client computing system and connect to the central backend management system 250 instead of connecting directly to the SCP end-point at the solar site.

Thus, manufacturing data may be stored in a relational database associated with a central backend management system. A plurality of concentrated photovoltaic (CPV) arrays are located at a remote solar site. Each of the CPV arrays and the components making up that CPV array is associated with its set of manufacturing data. The manufacturing data of the CPV arrays and the components making up that CPV array includes serial number information of the components of the CPV arrays and measured manufacturing data for those components, which allows a calculation of at least projected performance information of the CPV array during an actual operation of that CPV array at the remote solar site. The projected performance information of the CPV array may be compared to the actual performance information during the actual operation of that CPV array at the solar site.

The manufacturing data associated with components of a plurality of concentrated photovoltaic (CPV) arrays located at a remote solar site is stored. Each of the CPV arrays may coupled with a different system control point (SCP) communicatively connected to a central backend management system. Actual performance information of the components of the CPV arrays is received from their corresponding SCP using a secured and persistent connection and based on Hypertext Transfer Protocol Secure (HTTPS). Condition information at the remote solar site. Projected performance information of the components of the CPV arrays is determined based on the manufacturing data and the condition information at the remote solar site. The actual performance information of the components of the CPV arrays and their corresponding projected performance information is compared to determine whether the components of the CPV arrays are performing as expected.

### Graphical User Interface

A set of user interfaces (also referred to as dashboards) served by the central backend management system 250 provides the user experience of an on-line solution for the entire solar system. These user interfaces enable on site set up and diagnostics, remote management and trouble shooting, historical data storage & retrieval, visual presentation of the remote set of solar generation facilities over a public wide area network to its intended audience, and much more.

For some embodiments, a set of graphical user interfaces (GUIs) may be presented to the user by the central backend management system 250 once the user is authenticated. Each of the GUIs may include options to enable the user to operate and control one or many solar sites associated with the user. The GUIs may include options to enable onsite set up and diagnostics, remote management and troubleshooting, historical data storage and retrieval, visual presentation of the solar sites, etc. For example, the user may be able to view signal strength of the wireless router for every CPV array, the temperature of the inverter board, the position of every axis for every CPV array in relation to the sun, whether each axis of a CPV array is tracking or not and the accuracy of the tracking, the date and time when the tracker of a CPV array was last calibrated, basic predefined graphs on the portfolio, site, section, and array or string dashboard as a graph for a certain time period (e.g., one hour, one day, one week, one month, one year, etc.), the energy production performance as related to all the strings of a CPV array or all the substrings of a string, etc. It may be noted that, by using the browser software, the user can access the information related to the solar site and manage the solar site via the central backend management system 250 rather than having to connect directly to a device (e.g., the SCP 310) at the solar site.

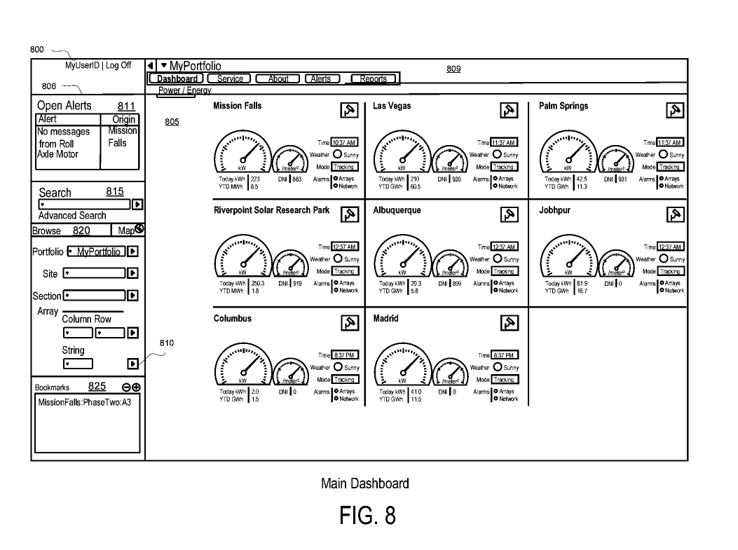

FIG. 8 is a diagram that illustrates an example a user interface associated with the central backend management system. Diagram 800 may be presented after the user is authenticated by the central backend management system 250. The diagram 800 includes a portfolio overview section 805 and dashboard tab section 809. The portfolio overview section 805 may display high-level or overview information about the solar sites in the portfolio of the user. The information may be displayed in a two dimensional array. The example in diagram 800 includes eight (8) solar sites—Mission Falls, Las Vegas, Palm Springs, Riverpoint Solar Research Park, Albuquerque, Jobhpur, Columbus and Madrid. It may be noted that even though these solar sites are located worldwide, the user may be able to manage and access information associated with these solar sites by connecting and logging into the central backend management system using the Internet.

As illustrated in FIG. 8, the overview information for each of the solar sites may include power/energy information, local time information, local weather information, alarm information, address information, video camera information, etc. The user may have the option of searching for a specific site, section, array or string and alternatively seeing the same information by drilling down the hierarchy of icons on the dashboard in order to view the drilled down site/array/string/tracker etc., overall status, alarm status, configuration information or manufacture information. The user may use the side panel 806 to drill down on to deeper levels of details about a particular solar site using browse options. Also in the side panel 806, the user may use the “+” button to save information in the favorite section for quick access to the same information (e.g., the energy information associated with a particular array of a solar site) at a subsequent time. An item in the favorite section may be a textual string that includes information about a particular site, section and array. A “−” button may be used to remove an item from the favorite section.

The central backend management system 250 may allow the user to define other users who can manage its solar site. The user may be able to add or remove portfolios, view all the solar sites in a portfolio, add and remove sites from a portfolio, etc. The user may be able to add or remove users that have any permission in the management of its portfolio via the central backend management system 250.

The dashboard tab section 809 includes dashboard tab, service tab, about tab, alerts tab and reports tab. Each of the tabs may be associated with one or more sub tabs. As will be described, each of the sub tabs may be associated with a different user interface and may present a different type of information or option to the user. Depending on how the user navigates the browse section 820 of the side panel 806, appropriate tab is activated and its associated sub tabs are available for the user to select. For example, when the dashboard tab is activated, the associated sub tabs power/energy, tracker, IV curves and camera are displayed. When the service tab is activated, the associated sub tabs maintenance, control and firmware are displayed. When the about tab is activated, the associated sub tabs configuration, network and components are displayed. When the reports tab is activated, the associated sub tabs performance and configurations are displayed. Selecting any of the sub tabs mentioned may cause information related to the sub tabs to be displayed in the main panel 805. For some embodiments, the user may use the browse section 820 to select a solar site displayed in the solar site overview section 805 to manage or access information related to that particular solar site.

The side panel 806 may include an alert section 811, a search section 815, a browse section 820, and a bookmarks section 825. The alert section 811 may be used to display alert information and to enable the user to view more details about certain alerts. The alert section 811 may allow the user to navigate to a particular alert by selecting or clicking on an alert name. The search section 815 may be used to enable the user to quickly search for information related to a component of a solar site that the user is associated with. The browse section 820 may be used to enable the user to browse information about a solar site by selecting parameters provided in pulled-down lists, thus enabling the user to drill down or access information at many different levels of details. The browse section 820 allows the user to navigate to the portfolio, the sites in the portfolio, the sections, arrays and individual strings in the solar site. When a navigation point (e.g., portfolio, site, section, array column, array row, and string) is selected, the activation arrow button 810 on the lower right of the browse section 820 may cause the appropriate dashboard to be displayed in the main panel 805. Each combination of navigation points may be associated with a different displayed graph in the panel. The side panel 806 may remain visible to the user regardless of where the user is in the process of managing the solar sites.

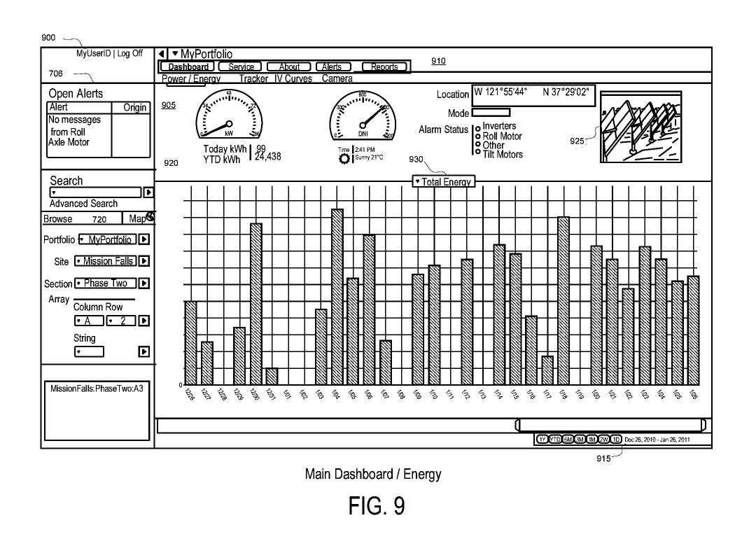

FIG. 9 is a diagram that illustrates an example main dashboard user interface that displays power/energy information. Diagram 900 may be presented after the user navigates the browse section 820 to select a solar site, section, array and string. It may be noted that the power/energy sub tab under the dashboard tab may be activated as a default.

The power/energy information is presented as a bar chart 920 with the vertical axis representing the total energy in kilowatts hour (kWh) and the horizontal axis representing the dates. The timeframe of the information displayed in the bar chart 920 is defaulted at one month. The lower right section 915 of the dashboard allows the user to select varying timeframes from one day to one year. In the current example, the diagram 900 also includes a video box 925 that shows a small streaming video of the solar site along with the time information, DNI information, weather information, current day and year-to-date energy information, alarm status, GPS location information, and mode information. The user may alternatively view the view of the information from total energy to power and DNI by selecting the pull down option 930.

Section 905 in the main panel of diagram 900 includes a gauge showing kWh per day and year to date, a gauge showing DNI, local time, the weather and temperature information, the latitude and longitude of the SCP 310. This section also shows the mode of the array (when an array is navigated to), an alert status area with changing LED type mode and a streaming video of the solar site.

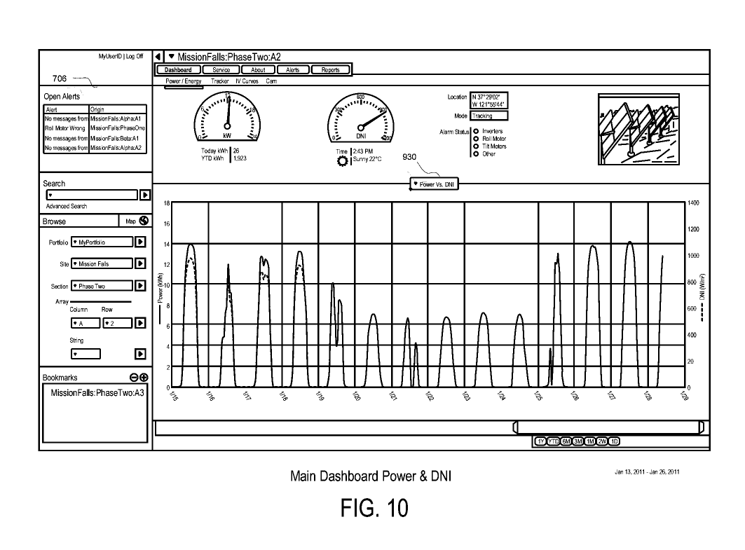

FIG. 10 is a diagram that illustrates an example main dashboard user interface that displays the power and DNI information. The power and DNI information illustrated provides a two-week timeframe view. The user may be able to check at a glance that an individual portfolio, site, section, array or string is producing energy as expected and that there are no problems. The user may be able to view near real time the performance of the solar site. The energy production information on the dashboard may include the energy produced since dawn and the energy produced since the beginning of the current year.

The central backend management system 250 may display data points on the displayed graph. The user may be able to view basic predefined graphs (e.g., power levels) on the portfolio, site, section, and array or string for a period of one hour, one day, one week, one month or one year. The user may specify an array and the data correlated with the data of the neighboring arrays.

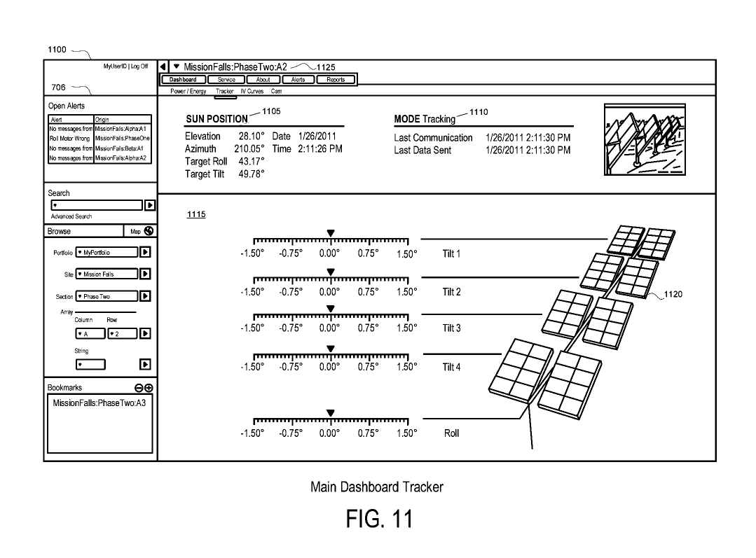

FIG. 11 is a diagram that illustrates an example main dashboard user interface that displays the tracker information. Diagram 1100 may be presented when the tracker sub tab under the dashboard tab is activated. The diagram 1100 includes the sun position information 1105, the mode information 1110, and the paddle pairs positioning information 1115. This may enable the user to view the paddle pairs and roll beam actual versus commanded positions. The dashboard with the tracker control capability reinforces the user's comfort level on the reliability, durability and accuracy of the dual tracking system by showing for every array a near real-time tracking status of various parameters. For example, the user will be able to view the position of every axis for every array in relation to the sun. The user may be able to find out whether each axis of an array is tracking and the accuracy of the tracking. The date and time information about when the tracker of an array was last calibrated may be presented to the user. The user may also be able to view configuration information for a motor control board of an array. An image 1120 of the roll beam and associated paddle pairs may be displayed to enable the user to view the position changes. It may be noted that the diagram 1100 also displays navigation information 1125 that corresponds to the information being displayed in the main panel section of the diagram 1100. This navigation information 1125 may be similar to the information stored in the favorite section if the user decides to save it.

The central backend management system 250 may be configured for proactive operation of a solar site and coordination between operators and field service personnel by remote control of the arrays. The central backend management system 250 may be configured for the user to request that an array or all of the arrays in a portfolio or a section to be put in normal tracking mode or another mode (e.g., stow mode). Responsive to the user's request to put the array into the tracking mode, the array will move to the appropriate position and start tracking the sun. The central backend management system 250 may be configured for the user to request that an array or all of the arrays in the portfolio or a section be put in a hazard or stow mode from another mode when a condition exists (e.g., severe weather). The central backend management system 250 may be configured to enable the user to have the option to define a cushion in a time unit (e.g., minutes) after sunset and before sunrise that make up a night mode. The user may be able to define horizon parameters to control the array from starting to track too early or from stopping to track too late, based on the possibility that there is no direct sunlight due to horizon issues (e.g., neighboring mountain range).

The current to voltage (or IV) curves sub tab may be used to request IV curve data from the SCP 310. It may take approximately 60 seconds for the data from the SCP 310 to get to the central backend management system 250. There may be a progress indicator to provide the user an indication of the progress while the user is waiting for the IV curve data to be received by the central backend management system 250. When the IV curves sub tab is activated, the user may be able to view which paddles are included in a string when viewing the string performance. The user may be able to view the last IV curves taken for all of the strings of an array or all of the substrings of a string. The user may be able to view the value of parameters for an array's inverter control board.

When the IV curves sub tab is activated, the central backend management system 250 is configured for the option of generating an angle map for an array, at which point the array moves to each of the positions defined for the angle map and generates an IV curve. After finishing the sequence, the array will resume its correct position relative to the sun if it is in auto-tracking mode. The array may operate in auto or manual tracking mode. The central backend management system 250 may also generate an angle map for a specific paddle pair in the solar array. The central backend management system may 250 also generate an IV curve for the strings of an array or the substrings of a string. The central backend management system 250 may also show the set of geographical coordinates for a section and the array mapped to each. The central backend management system 250 may also generate the location of an array and its parameters within a section when viewing array performance.

The user may be able to request that an array calibrate itself. The central backend management system 250 is configured for maximum performance and efficiency by allowing remote diagnostics and calibration upon the user request. When in the diagnostic mode, the user may be able to enter the roll and tilt position information for a CPV array, and then initiate a request for the CPV array to move based on that position information. The user may be able to issue a request to immediately turn on or turn off the strings of each individual CPV array.

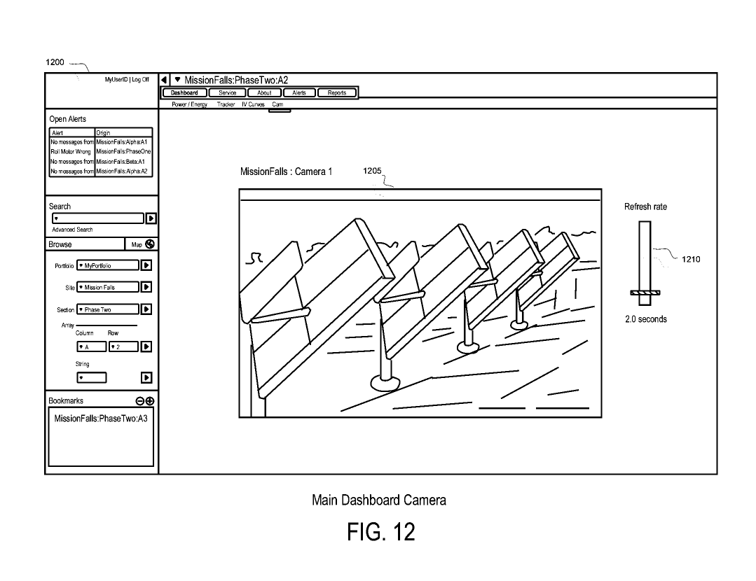

FIG. 12 is a diagram that illustrates an example main dashboard user interface that displays the camera information. Diagram 1200 may be presented when the camera sub tab under the dashboard tab is activated. The user may receive almost live video feed at all times via a video camera that is installed at the solar site. A large streaming video display area 1205 may enable the user to view the solar site. The user interface allows the user to enter a list of arrays or a single array that is to be monitored by the video camera. The user interface may also have zoom options to enable the user to zoom in certain area of the solar site in near real time. The user may use the refresh option 1210 to change the camera refresh rate by moving the refresh slider. It may be noted that the diagram 1200 may be navigated to by selecting or clicking on the inset streaming video box 925 illustrated in FIG. 9.

The user may be able to access topological map of a solar site when viewing the site performance information. The user may be able to view the current settings for a CPV array including inverter and motor parameters, frequency of energy calculation, communication retry frequency in case of failures, etc. The dashboard may show performance of a portfolio, site, section, array or string with power versus DNI and current DNI, weather and projected power so that energy production levels can be analyzed in the context of existing conditions. The projected power may not include DNI calculations, but it may be based on the base specifications of all the components.

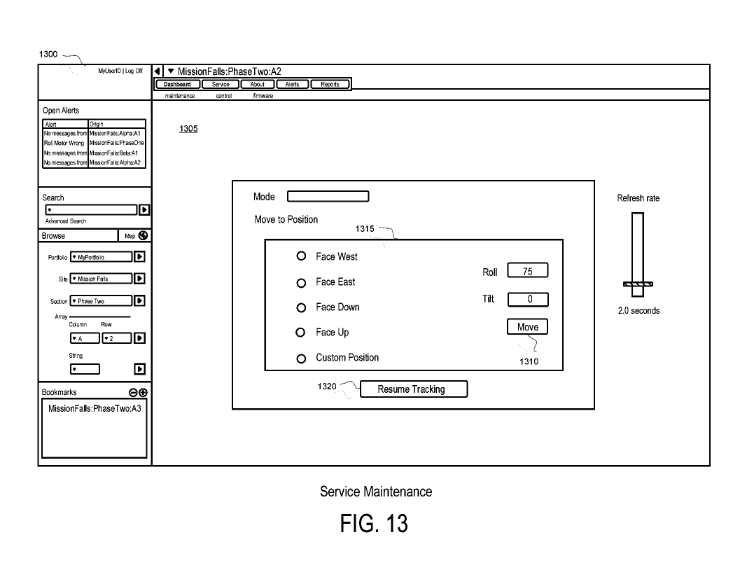

FIG. 13 is a diagram that illustrates an example main dashboard user interface that displays the maintenance information. Diagram 1300 may be presented when the service tab in the dashboard tab section 809 and its associated maintenance sub tab is activated. For some embodiments, this option may only be presented if the user is authenticated to perform service operations. Warning messages (e.g., pop-up windows) may be presented to ensure that the user understands that any operations performed by the user may change the energy production. As mentioned, the service tab includes a maintenance sub tab, a control sub tab and a firmware sub tab.

For some embodiments, when the service tab is activated, the maintenance sub tab is activated as a default. When the move button 1310 is selected or clicked, the array may enter a manual mode. Current position information may be displayed in the tracking input section 1315. When the maintenance operation is complete, the resume-tracking button 1320 may need to be selected or clicked to resume the energy production.

When the control sub tab under the service tab is activated, the user may be able to manipulate the array roll and each of the four tilt positions. The control sub tab may be used to assist in the initial leveling, referencing and calibrating of the roll and tilt axis of the CPV array. When the operations associated with the control sub tab is completed, the user may need to navigate back to the maintenance sub tab and select the resume-tracking button 1320 to resume the energy production.

When the firmware sub tab under the service tab is activated, the user may be able to update the software packages for the array. As with the control sub tab, the user may need to navigate back to the maintenance sub tab and select the resume-tracking button 1320 to resume the energy production.

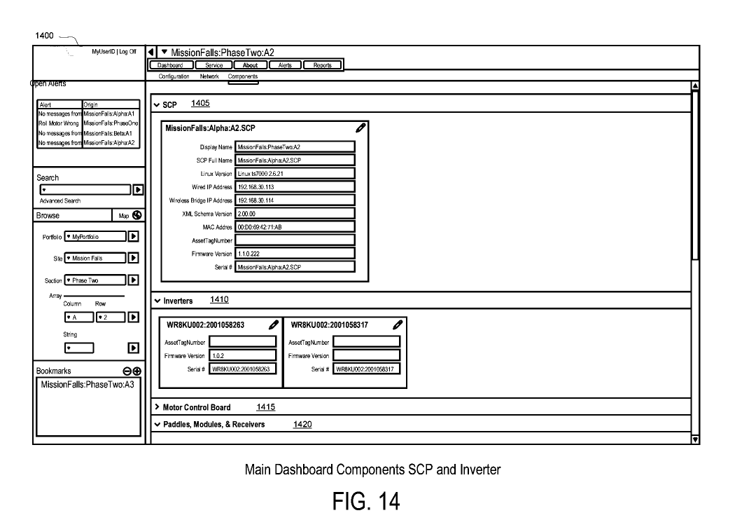

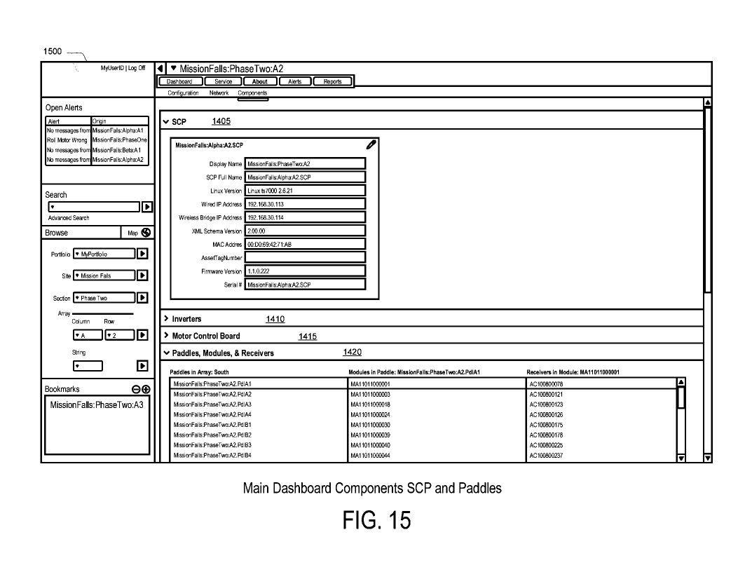

FIG. 14 is a diagram that illustrates an example main dashboard user interface that displays the component information. Diagram 1400 may be presented when the about tab in the dashboard tab section 809 and its associated component sub tab is activated. For some embodiments, activating the component sub tab may provide the user a view of the parameters of the CPV array. The view of the parameter of the CPV array may include the SCP view 1405, the inverter view 1410, the motor control board view 1415, and the paddle, module, and receivers view 1420. Each of these four views may be visible by selecting the appropriate heading. In the current example, only the SCP view 1405 and the inverter view 1410 are illustrated. FIG. 15 is similar to FIG. 14 except it illustrates the SCP view 1405 and the paddle, module, and receivers view 1420. When the configuration sub tab is activated, current configuration information of the components of the CPV array may be presented in the main panel. When the network sub tab is activated, the network information may be presented.

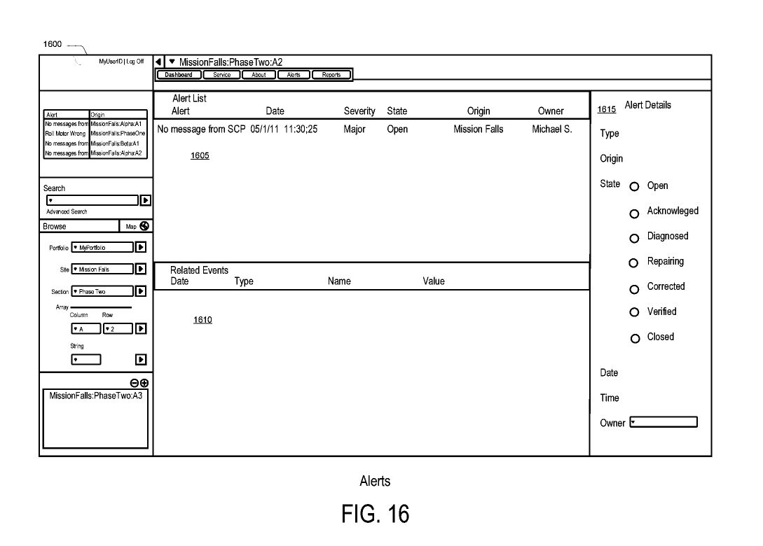

FIG. 16 is a diagram that illustrates an example main dashboard user interface that displays the alert information. Diagram 1600 may be presented when the alerts tab in the dashboard tab section 809 is activated. Diagram 1600 includes an alert list section 1605, an alert related events section 1610, and an alert details section 1615. Each alert in the alert list section 1605 is associated with a set of alert details displayed in the alert details section 1615. The alert details may include the status of the alert and the owner or person responsible for handling the alert. The alert list may display the severity of the alert, its origin, and the date and time when the alert is generated. The related events section 1610 may display other events that may be occurring when the alert is generated. This may help the user diagnose why the alert is generated and take the appropriate correction actions.

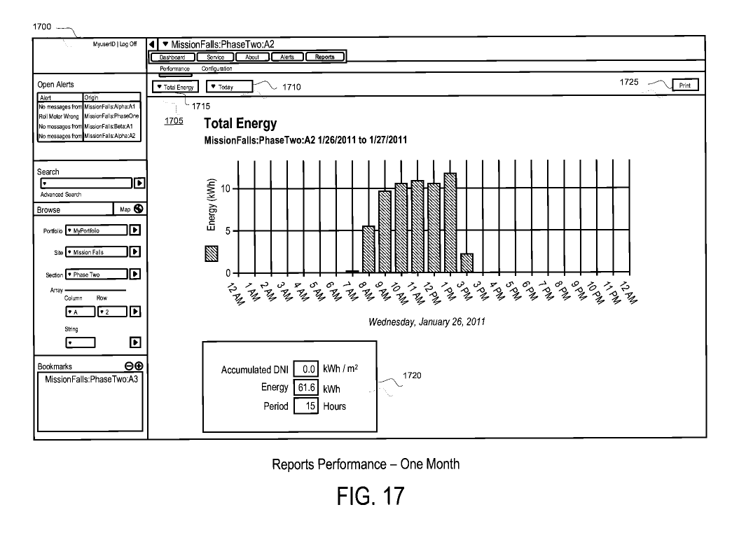

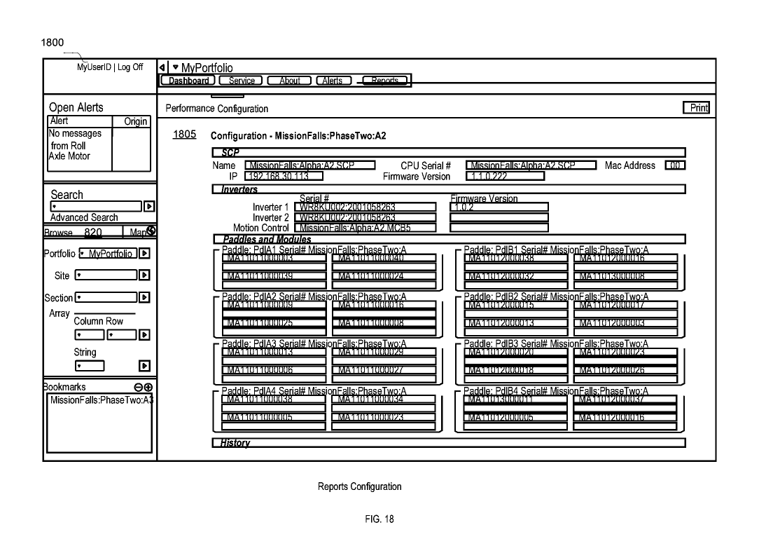

FIG. 17 is a diagram that illustrates an example main dashboard user interface that displays the performance information. Diagram 1700 may be presented when the reports tab in the dashboard tab section 809 and its associated performance sub tab are activated. Diagram 1700 may include a bar chart that displays total energy information for a particular timeframe. The timeframe may be changed by selecting the timeframe pull down button 1710. This may enable changing the timeframe from a day to a week, a previous week, a month, or it can be set to a custom range. The bar chart may be changed to show the power and DNI information by selecting the pull down button 1715. A summary of the total energy and DNI information for the selected timeframe is displayed in box 1720. The user may use the print option 1725 to print a copy of the report.

FIG. 18 is a diagram that illustrates an example main dashboard user interface that displays the configuration information. Diagram 1800 may be presented when the reports tab in the dashboard tab section 809 and its associated configuration sub tab are activated. Using this option, the user may be able to view how each component is configured, its serial number information, applicable firmware information, etc. As illustrated, the configuration information area 1805 may include configuration information for the SCP 310 (e.g., IP address, MAC address, serial number, etc.), the inverters (e.g., serial number, motion control, firmware, etc.), and the paddles, modules and receivers (e.g., serial numbers, etc.) in each of the arrays.

The reports tab may also include one or more sub tabs that enable the user to create and/or view standard or custom reports. The user may create custom reports using power, energy produced, DNI, and weather at the portfolio, site, section and array level. The user may have the option of filtering for specific portfolio, sites, sections, arrays or set. The user may be able to view the reports on the history of component changes for every component type (e.g., module, motor, SCP, mechanical component) or for all components. The user may view a standard weather and solar report. The user may view the manufacturing data, the performance information and history associated with a component. The user may also use this user interface to view other reports.

The information displayed in the configuration information area 1805 includes the serial numbers of the inverters and the serial numbers of the paddles in the CPV array. The serial numbers of the inverters and the paddles are portions of the overall manufacturing data associated with the CPV array that may be stored in the manufacturing data database of the central backend management system 250. In general, the serial numbers for each of the components in the tracker, the inverter circuits, the CPV array, the paddles, the modules in the paddles, the lens and other related components may also be stored in the database. The manufacturing data may also include manufacturing date, tested characteristics and projected performance information for some or all of the components.

For some embodiments, database tables or templates may be configured to store the manufacturing data. The database tables may include fields that correspond to the manufacturing data as well as fields that may be used for locally assigned information (e.g., asset number, component display name, etc.). When the components are installed in the solar site, the manufacturing data of the components as well as their locations may be recorded. The recorded information may then be used to populate the fields of the database tables and stored in the manufacturing data database. Some or all of the fields in the database tables used to store the manufacturing data may be linked to one another. This may enable the manufacturing data to be aggregated based on one or more of the fields making it convenient to process related manufacturing data.

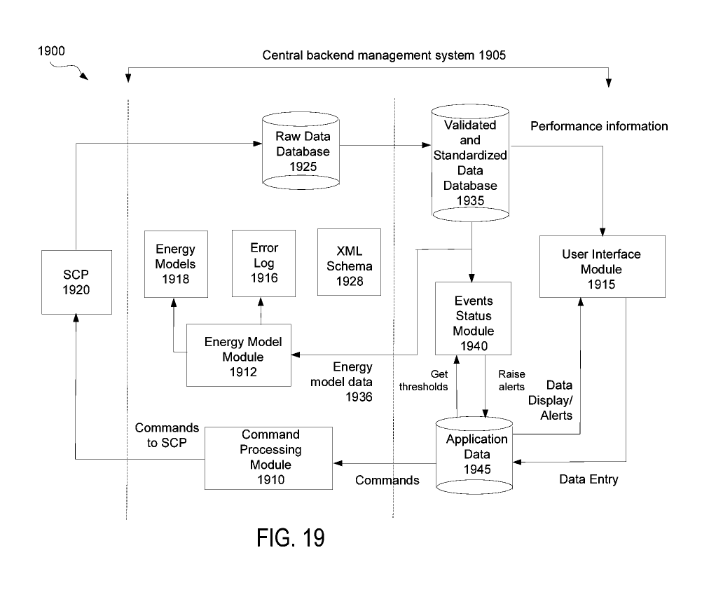

FIG. 19 is a diagram that illustrates example modules of a central backend management system that may be used to generate alarms associated with a solar site. Diagram 1900 includes a central backend management system 1905 and a SCP 1920. The central backend management system 1905 includes a command processing module 1910 and events status module 1940. For some embodiments, either or both of the central backend management system 1905 and the SCP 1920 may be configured to compare parameters received from the various components of the solar site with threshold values to determine whether alarm conditions occur and alarms and/or events should be generated. The thresholds may be customizable on a per-inverter basis, and they may be based on an actual manufacturing data for that inverter rather than a baseline value for every inverter. For example, the user may be sent an alert if the performance of a CPV array or a string in the CPV array degrades by over the threshold of 20% while in the tracking or manual mode as compared to the performance of any of its neighboring CPV arrays. The user may have the option of changing the threshold of 20% to a different threshold value. The thresholds may be stored in the application data database 1945.

Information collected and transmitted by the SCP 1920 to the central backend management system 1905 may be stored in the database 1925 as raw data. It is possible that the data stored in the database 1925 include status information and/or alarms transmitted by the SCP 1920 to the central backend management system 1905. This may include, for example, array string status, tracker status, motor status, weather solar status, field event parameters, etc. The data (e.g., raw data received from the SCP 1920) in the database 1925 may be validated, standardized. XML schema 1928 may be enforced. The validated and standardized data may be stored in the database 1935. The user interface module 1915 may process some of these data and present them to the user. The events status module 1940 may process some of these data to determine if alarms need to be generated.

These alarms may be presented to the user along with a history of events and/or parameters that occur within a certain period (e.g., the last 10 to 30 minutes) of when the alarms are generated. This enables the user to view the events that may be related to the cause of the alarms. The user may be able to define a timeframe before and after an alarm where events that occur during that timeframe are to be displayed with the alarm status. This enables the user to make a quicker assessment of any problems that may be occurring at the solar site. The alarms may be presented to the user via the dashboards by the user interface module 1915. As described above, alerts may also be generated and presented to the user via the dashboards when the collective “as built” performance information for any array is different from the actual performance during a certain period of time and by a defined margin.

As illustrated in FIG. 16, the user interface may include alarms tab that shows the user contextual information when viewing an alarm at the section, array or string level. For example, the user may be presented with information about the portfolio, the solar site, the section, and the CPV array when the user is viewing a string level alarm. The user interface may display status that includes a list of alarms sorted by priority and by date. There may be indicators specifying whether the inverter, the motor or other alarms are outstanding and need to be handled. The user may be able to filter alarms by level, such as portfolio level alarms, site-level alarms, section level alarms, array level alarms, string level, type and severity alarms. The central backend management system 1905 may provide transparency by showing log of events in chronological order, even for events that do not have alarms configured. The central backend management system 1905 may guide the users on the proper operation of a solar site by predefining alarms around key events. The user may have the ability to specify a recipient of a set of recipient of the alarms based on their email addresses.

The central backend management system 1905 may transmit commands to the SCP 1920 to manage the components at the solar array. The commands may be initiated based on the user entering data and selecting options available via the dashboards. The data entered by the user may be stored in the application data database 1945. Depending on the data and the options initiated by the user, the command module 1910 may process the data as commands for the appropriate components at the solar site. As described, these commands may be transmitted to the SCP 1920 in the forms of HTTPS message acknowledgement.

The application data database 1945 may store information about all of the components/modules on an array including their position in the paddle/array, serial number, manufacturing date, “as built” output voltage level, etc. The user interface module 1915 may retrieve this information from the application data database 1945 and present them to the user via the appropriate dashboards. The user may be able to view the SCP serial number, date of manufacture and part number for any array in the solar site. The user may be able to view the serial number, model number and part number for every mechanical component of the array that have a serial number including, for example, the SCP, the motor control board, the inverter, the motor, the paddle, etc. The application data database 1945 may store a history of motors and other mechanical components of the array that have a serial number and used on an array. The application data database 1945 may store the manufacturing and performance history for all of the components including the motor control board and inverter board for every SCP. The combination of the databases 1925, 1935, and 1945 illustrated in FIG. 19 may be referred to collectively as the database of the central backend management system 1905 as described in the previous sections.

### Energy Model

The central backend management system 1905 is configured to perform numerous other operations to deliver associated sets of data. For example, when the actual power data is presented, the weather condition corresponding that solar site is also presented. Similarly, when the actual power data is presented, the projected power data (as included in the manufacturing data) may also be presented alongside. The projected power data that is included in the manufacturing data may be available for various components including the photovoltaic cells, circuit cards, etc. In this example, the projected performance or power data may be stored in the database 1935 so a comparison of the actual performance data to the projected performance data may be made. The central backend management system 1905 may also include many other of helpful management tools to enable the user to observe exactly what is happening to each component in the remote site with much greater level of granularity including. For example, the user may be able to view the performance information for the CPV array, a string in the CPV array, cells in the CPV array, etc. Performance information associated with the paddles of a CPV array may be compared with performance information of the paddles of a neighboring CPV array.

For some embodiments, the central backend management system 1905 may include an energy model module 1912 configured to retrieve the energy model data from the database 1935. The energy model data 1936 may include the projected power data from the manufacturer, the condition information at the solar site, and the actual performance data at the solar site. Application programming interface (API) may be available to enable user applications to interact with the energy model module 1912. The energy model module 1912 may apply the energy model data 1936 to generate the different energy models 1918. The energy models 1918 may include site-specific energy models and/or CPV array specific energy models. The energy model module 1912 may generate reports or files that can be exported to enable the user to perform own analysis.

The energy modeling operations performed by the energy model module 1912 may set performance monitoring and alerts, determine expected performance, and compare actual versus projected performance data. The energy modeling operations may allow the user to be able to validate if any underproduction of energy is due to lower DNI or due to a faulty component. The user may be able to determine whether the solar site is performing as projected because the user has the ability to correlate the actual performance data of every component in the solar site with its corresponding projected data. In other examples, a site-specific energy model may enable the user to determine array orientation and layout, shadowing effects, proper inter-array spacing, and possible site obstructions. The energy model module 1912 may be configured to allow the user to enter site geometry, coordinates, meteorology, and topography, and it may prove estimated power output based on those entries. A meteorology/irradiance energy model can use National Oceanic and Atmospheric Administration (NOAA) weather forecasts, DNI data, and local weather observations to produce energy estimations. The energy model described above may be referred to as an engineering energy model since it allows the user to configure and test different setting variations.

The energy model module 1912 may also be configured to generate sales, contract or warranty energy models. The sales, contract or warranty energy model may allow the user to provide an accurate prediction of the performance of a particular solar site. The sales, contract or warranty energy models may be used the users who are project developers and financiers. For example, the user may be able to use the energy model module 1912 to generate the warranty energy models that show the energy production for the current year. This may enable the user to verify that the power purchase agreement (PPA) is in good standing. It may be noted that the engineering energy model may be scripted to be highly granular and detailed and supplies more detailed information available than the general estimates a warranty energy model may provide.

### Use of Manufacturing Data Flow Diagram

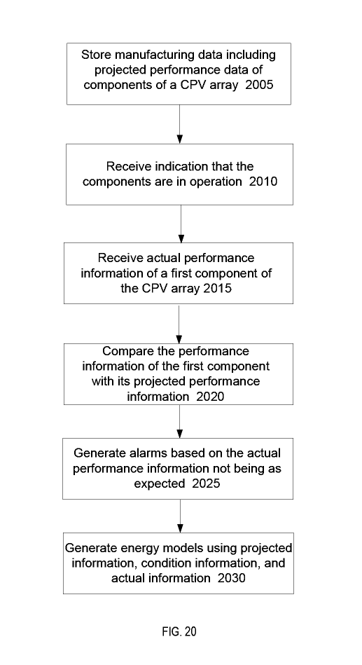

FIG. 20 is a flow diagram that illustrates an embodiment of a process that may be used to process the manufacturing data. The process may be performed by the central backend management system. The process may start at block 2005 where the manufacturing data of the components of the CPV arrays are installed at a solar site. As described with FIGS. 3B and 7A, when a new paddle, SCP, or any components associated with a CPV array is installed in the solar site, the installation team may record the serial number of the component as well as its corresponding manufacturing data. The manufacturing data may include projected performance information of the components and may be stored in the manufacturing data database. At block 2010, the central backend management system may receive an indication that the components are ready to be in operation. At block 2015, actual field performance information may be received from the SCP. At bock 2020, the actual field performance information is compared with the projected performance information. At block 2025, alarms may be generated when the actual field performance information is not consistent with the projected performance information. Recent history of events and parameters may also be presented with the alarms in order to allow the user to assess problems associated with the alarms. At block 2030, energy models may be generated. This may include the engineering energy models and/or warranty energy models.

With reference to FIG. 1, for some embodiments, computing system environment 100 may be used by a client to access, control, and manage solar-related resources at one or more solar sites from a remote location. As will be described, the solar site may include many solar arrays, modules, paddles, tracker axis, etc. A client or user may use the computing system environment 100 to connect to a central backend management system over a network such as the Internet.

The computing system environment 100 is only one example of a suitable computing environment, such as a client device, and is not intended to suggest any limitation as to the scope of use or functionality of the design. Neither should the computing system environment 100 be interpreted as having any dependency or requirement relating to any one or combination of the illustrated components.

The design is operational with numerous other general purpose or special purpose computing system environments or configurations. Examples of well-known computing systems, environments, and/or configurations that may be suitable for use with the design include, but are not limited to, personal computers, server computers, hand-held or laptop devices, multiprocessor systems, microprocessor-based systems, set top boxes, programmable consumer electronics, network PCs, minicomputers, mainframe computers, distributed computing environments that include any of the above systems or devices, and the like.

The design may be described in the general context of computing device executable instructions, such as program modules, being executed by a computer. Generally, the program modules include routines, programs, objects, components, data structures, etc., that perform particular tasks or implement particular abstract data types. Those skilled in the art can implement the description and/or figures herein as computer-executable instructions, which can be embodied on any form of computing machine readable media discussed below.

The design may also be practiced in distributed computing environments where tasks are performed by remote processing devices that are linked through a communications network. In a distributed computing environment, program modules may be located in both local and remote computer storage media including memory storage devices.

With reference to FIG. 1, an exemplary computing type system for implementing the design includes a general-purpose computing device in the form of a computing device 110. Components of computing device 110 may include, but are not limited to, a processing unit 120 having one or more processing cores, a system memory 130, and a system bus 121 that couples various system components including the system memory to the processing unit 120. The system bus 121 may be any of several types of bus structures including a memory bus or memory controller, a peripheral bus, and a local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) locale bus, and Peripheral Component Interconnect (PCI) bus.

Computing device 110 typically includes a variety of computing machine-readable media. Computing machine-readable media can be any available media that can be accessed by computing device 110 and includes both volatile and nonvolatile media, removable and non-removable media. By way of example, and not limitation, computing machine-readable mediums uses include storage of information, such as computer readable instructions, data structures, program modules or other data. Computer storage mediums include, but are not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by the computing device 110. Communication media typically embodies computer readable instructions, data structures, program modules, or other transport mechanism and includes any information delivery media.

The system memory 130 includes computer storage media in the form of volatile and/or nonvolatile memory such as read only memory (ROM) 131 and random access memory (RAM) 132. A basic input/output system 133 (BIOS), containing the basic routines that help to transfer information between elements within computing device 110, such as during start-up, is typically stored in ROM 131. RAM 132 typically contains data and/or program modules that are immediately accessible to and/or presently being operated on by processing unit 120. By way of example, and not limitation, FIG. 1 illustrates operating system 134, application programs 135, other program modules 136, and program data 137.

The computing device 110 may also include other removable/non-removable volatile/nonvolatile computer storage media. By way of example only, FIG. 1 illustrates a hard disk drive 141 that reads from or writes to non-removable, nonvolatile magnetic media, a magnetic disk drive 151 that reads from or writes to a removable, nonvolatile magnetic disk 152, and an optical disk drive 155 that reads from or writes to a removable, nonvolatile optical disk 156 such as a CD ROM or other optical media. Other removable/non-removable, volatile/nonvolatile computer storage media that can be used in the exemplary operating environment include, but are not limited to, USB drives and devices, magnetic tape cassettes, flash memory cards, digital versatile disks, digital video tape, solid state RAM, solid state ROM, and the like. The hard disk drive 141 is typically connected to the system bus 121 through a non-removable memory interface such as interface 140, and magnetic disk drive 151 and optical disk drive 155 are typically connected to the system bus 121 by a removable memory interface, such as interface 150.

The drives and their associated computer storage media discussed above and illustrated in FIG. 1, provide storage of computer readable instructions, data structures, program modules and other data for the computing device 110. In FIG. 1, for example, hard disk drive 141 is illustrated as storing operating system 144, application programs 145, other program modules 146, and program data 147. Note that these components can either be the same as or different from operating system 134, application programs 135, other program modules 136, and program data 137. Operating system 144, application programs 145, other program modules 146, and program data 147 are given different numbers here to illustrate that, at a minimum, they are different copies.

A user may enter commands and information into the computing device 110 through input devices such as a keyboard 162, a microphone 163, and a pointing device 161, such as a mouse, trackball or touch pad. Other input devices (not shown) may include a joystick, game pad, satellite dish, scanner, or the like. These and other input devices are often connected to the processing unit 120 through a user input interface 160 that is coupled to the system bus, but they may be connected by other interface and bus structures, such as a parallel port, game port or a universal serial bus (USB). A monitor or display 191 or other type of display device is also connected to the system bus 121 via an interface, such as a video interface 190. In addition to the monitor, computers may also include other peripheral output devices such as speakers 197 and printer 196, which may be connected through an output peripheral interface 190.

The computing device 110 may operate in a networked environment using logical connections to one or more remote computers, such as a remote computer 180. The remote computer 180 may be a personal computer, a hand-held device, a server, a router, a network PC, a peer device or other common network node, and typically includes many or all of the elements described above relative to the computing device 110. The logical connections depicted in FIG. 1 include a local area network (LAN) 171 and a wide area network (WAN) 173, but may also include other networks. Such networking environments are commonplace in offices, enterprise-wide computer networks, intranets and the Internet. A browser application may be resident on the computing device and stored in the memory.

When used in a LAN networking environment, the computing device 110 is connected to the LAN 171 through a network interface or adapter 170. When used in a WAN networking environment, the computing device 110 typically includes a communication module 172 or other means for establishing communications over the WAN 173, such as the Internet. The communication module 172 may be a modem used for wired, wireless communication or both. The communication module 172 may be internal or external, may be connected to the system bus 121 via the user-input interface 160, or other appropriate mechanism. In a networked environment, program modules depicted relative to the computing device 110, or portions thereof, may be stored in the remote memory storage device. By way of example, and not limitation, FIG. 1 illustrates remote application programs 185 as residing on remote computer 180. It will be appreciated that the network connections shown are exemplary and other means of establishing a communications link between the computers may be used.

It should be noted that the present design can be carried out on a computing system such as that described with respect to FIG. 1. However, the present design can be carried out on a server, a computer devoted to message handling, or on a distributed system in which different portions of the present design are carried out on different parts of the distributed computing system.

Another device that may be coupled to bus 111 is a power supply such as a battery and alternating current (AC) adapter circuit. As discussed above, the DC power supply may be a battery, a fuel cell, or similar DC power source that needs to be recharged on a periodic basis. For wireless communication, the communication module 172 may employ a Wireless Application Protocol to establish a wireless communication channel. The communication module 172 may implement a wireless networking standard such as Institute of Electrical and Electronics Engineers (IEEE) 802.11 standard, IEEE std. 802.11-1999, published by IEEE in 1999.

While other systems may use, in an independent manner, various components that may be used in the design, a comprehensive, integrated system that addresses the multiple advertising system points of vulnerability described herein does not exist. Examples of mobile computing devices may be a laptop computer, a cell phone, a personal digital assistant, or other similar device with on board processing power and wireless communications ability that is powered by a Direct Current (DC) power source that supplies DC voltage to the mobile device and that is solely within the mobile computing device and needs to be recharged on a periodic basis, such as a fuel cell or a battery.

Although the foregoing embodiments have been described in some detail for purposes of clarity of understanding, the invention is not limited to the details provided. Functionality of circuit blocks may be implemented in hardware logic, active components including capacitors and inductors, resistors, and other similar electrical components. There are many alternative ways of implementing the invention. The disclosed embodiments are illustrative and not restrictive.

We claim:

1. A method for enabling access to information associated with a concentrated photovoltaic (CPV) array installed in a solar site having multiple CPV arrays, the method comprising:
storing manufacturing data associated with components of a plurality of concentrated photovoltaic (CPV) arrays located at a remote solar site, each of the CPV arrays is coupled with a different system control point (SCP) communicatively connected to a central backend management system, wherein the manufacturing data includes at least projected performance information of the components of the CPV arrays, and wherein each of the CPV arrays is contained on a two-axis tracker mechanism;
receiving actual performance information of the components of the CPV arrays from their corresponding SCP using a secured and persistent connection and based on Hypertext Transfer Protocol Secure (HTTPS); and
generating alarm information based on the actual performance information of the components of the CPV arrays not being consistent with their corresponding projected performance information.

2. The method of claim 1, further comprising:
receiving condition information at the remote solar site from the SCP; and
comparing the actual performance information of the components of the CPV arrays with their corresponding projected performance information based on the condition information.

3. The method of claim 2, further comprising correlating the actual performance information and the projected performance information of the components of the CPV arrays and the condition information at the remote solar site to generate energy models to enable the user to generate different energy models including site-specific energy models, CPV array specific energy models, and any combination of both.

4. The method of claim 3, wherein the condition information at the remote solar site includes direct normal incidence (DNI) information and weather information, and wherein the energy models include engineering energy models and warranty energy models.

5. The method of claim 1, further comprising:
enabling the manufacturing data to be viewable by a user over an Internet based on the user using a browser in a client computing system;
enabling the alarm information to be viewable by the user over the Internet using the browser, wherein the alarm information includes an identity of the solar site and a severity level; and
enabling a history of events related to the alarm information to be viewable by the user using the browser, wherein the history of events includes events that occur during a predetermined time period prior to when the alarm information is generated.

6. The method of claim 5, further comprising enabling the user to use the browser to manage, service and track warranties of the components of the CPV arrays over the Internet using the manufacturing data.

7. The method of claim 1, further comprising comparing the actual performance information of the components of the CPV arrays with predetermined thresholds to determine whether the components of the CPV arrays are performing as expected.

8. The method of claim 1, wherein the manufacturing data includes serial number information and manufacturing date of the components of the CPV arrays, and wherein database templates including fields that correspond to the actual performance information, the serial number information, and the manufacturing date are generated and stored in a relational database associated with the central backend management system.

9. A method for a concentrated photovoltaic (CPV) array system, comprising:
storing manufacturing data in a relational database associated with a central backend management system, where a plurality of concentrated photovoltaic (CPV) arrays are located at a remote solar site and each of the CPV arrays and the components making up that CPV array is associated with its set of manufacturing data, where the manufacturing data of the CPV arrays and the components making up that CPV array includes serial number information of the components of the CPV arrays and measured manufacturing data for those components, which allows a calculation of at least projected performance information of the CPV array during an actual operation of that CPV array at the remote solar site; and
comparing the projected performance information of the CPV array to the actual performance information during the actual operation of that CPV array at the solar site, where the actual performance information of the components of the CPV arrays and their corresponding projected performance information is compared to determine whether the components of the CPV arrays are performing as expected.

10. A concentrated photovoltaic (CPV) array management system, comprising:
a plurality of concentrated photovoltaic (CPV) arrays located at a remote solar site, each of the CPV arrays associated with a different system control point (SCP) which is communicatively connected to a central backend management system over an Internet using a secured channel and Hypertext Transfer Protocol Secure (HTTPS),
wherein each of the CPV arrays is associated with a set of manufacturing data stored in a relational database associated with the central backend management system, the manufacturing data including at least projected performance information and serial number information of components of the CPV arrays, wherein each of the CPV arrays is contained on a two-axis tracker mechanism, and
wherein the central backend management system includes an energy model module configured to receive the projected performance information of the components of the CPV array, actual performance information of the components of the CPV arrays, and condition information at the remote solar site to generate site-specific energy models and/or CPV array specific energy models.

11. The system of claim 10, wherein the central backend management system includes an event status module configured to compare the projected performance information of the components of the CPV array with the actual performance information of the components of the CPV arrays and to generate alarm information based on the actual performance information of the components of the CPV arrays not being consistent with their corresponding projected performance information.

12. The system of claim 11, wherein the central backend management system further includes a user interface module configured to present the alarm information and a history of events that occur during a predetermined time period prior to when the alarm information is generated.

13. The system of claim 12, wherein the alarm information and the history of events are viewable by a user using a browser in a client computing system communicatively connected to the central backend management system over the Internet.

14. The system of claim 10, wherein the condition information at the remote solar site includes direct normal incidence (DNI) information and weather information, and wherein the energy models include engineering energy models and warranty energy models.

15. The system of claim 10, wherein database templates including fields that correspond to the actual performance information, the serial number information, and manufacturing date of the components of the CPV arrays are generated and stored in the relational database associated with the central backend management system.

16. A computer-readable media that stores instructions, which when executed by a machine, cause the machine to perform operations comprising:
storing manufacturing data associated with components of a plurality of concentrated photovoltaic (CPV) arrays located at a remote solar site, each of the CPV arrays is coupled with a different system control point (SCP) communicatively connected to a central backend management system;
receiving actual performance information of the components of the CPV arrays from their corresponding SCP using a secured and persistent connection with a protocol that verifies the identity of both a sending and receiving device;
receiving condition information at the remote solar site;
determining projected performance information of the components of the CPV arrays based on the manufacturing data and the condition information at the remote solar site; and
comparing the actual performance information of the components of the CPV arrays with their corresponding projected performance information.

17. The computer-readable media of claim 16, further comprising:
generating alarm information based on the actual performance information of the components of the CPV arrays not being consistent with their corresponding projected performance information; and
presenting the alarm information to a user via a user interface viewable with a browser in a client computing system, where the protocol that verifies the identity is Hypertext Transfer Protocol Secure (HTTPS).

18. The computer-readable media of claim 17, further comprising presenting a history of events that occur during a predetermined time period prior to when the alarm information is generated to the user using the same user interface.

19. The computer-readable media of claim 17, wherein each of the CPV arrays is contained on a two-axis tracker mechanism, wherein the manufacturing data is stored using database templates of a relational database associated with the central backend management system, and wherein the database templates include fields that are linked to one another to enable the manufacturing data to be aggregated.

20. The computer-readable media of claim 16, wherein the condition information includes temperature information, weather information, and direct normal incidence (DNI) information at the remote solar site, and wherein the central backend management system is configured to use the projected performance information of the components of the CPV array, the actual performance information of the components of the CPV arrays, and the condition information at the remote solar site to generate site-specific energy models and/or CPV array specific energy models.
